(19) United States
(12) Patent Application Publication
(10) Pub. No.: US 2023/0343854 A1
(43) Pub. Date: Oct. 26, 2023

(54) SPACER STRUCTURES IN SEMICONDUCTOR DEVICES

(71) Applicant: Taiwan Semiconductor Manufacturing Co., Ltd., Hsinchu (TW)

(72) Inventors: Huan-Chieh SU, Changhua County 520 (TW); Lin-Yu Huang, Hsinchu (TW); Chih-Hao Wang, Hsinchu County 308 (TW)

(73) Assignee: Taiwan Semiconductor Manufacturing Co., Ltd., Hsinchu (TW)

(21) Appl. No.: 17/879,529

(22) Filed: Aug. 2, 2022

Related U.S. Application Data
(60) Provisional application No. 63/333,835, filed on Apr. 22, 2022.

(51) Int. Cl. H01L 29/66; H01L 29/06; H01L 29/423; H01L 29/08; H01L 29/786; H01L 29/775; H01L 21/8234

(52) U.S. Cl. CPC H01L 29/6656; H01L 29/0673; H01L 29/42392; H01L 29/0847; H01L 29/78696; H01L 29/775; H01L 29/66439; H01L 21/823412; H01L 21/823418; H01L 21/823468

(57) ABSTRACT

A semiconductor device with air spacer structures and a method of fabricating the same are disclosed. The semiconductor device includes a substrate, nanostructured channel regions disposed on the substrate, a gate structure surrounding the nanostructured channel regions, a first air spacer disposed on the gate structure, a source/drain (S/D) region disposed on the substrate, and a contact structure disposed on the S/D region. The contact structure includes a silicide layer disposed on the S/D region, a conductive layer disposed on the silicide layer, a dielectric layer disposed along a sidewall of the conductive layer, and a second air spacer disposed along a sidewall of the dielectric layer.

### CROSS-REFERENCE TO RELATED APPLICATION

This application claims the benefit of U.S. Provisional Patent Application No. 63/333,835, titled “Semiconductor Device Structure,” filed on Apr. 22, 2022, the disclosure of which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around FETs (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1 illustrates an isometric view of a semiconductor device, in accordance with some embodiments.

FIGS. 2A-5C illustrate cross-sectional views of a semiconductor device with air spacer structures, in accordance with some embodiments.

FIG. 6 is a flow diagram of a method for fabricating a semiconductor device with air spacer structures, in accordance with some embodiments.

FIGS. 7A-7Q illustrate cross-sectional views of a semiconductor device with air spacer structures at various stages of its fabrication process, in accordance with some embodiments.

FIG. 8 is a flow diagram of a method for fabricating another semiconductor device with air spacer structures, in accordance with some embodiments.

FIGS. 9A-9I illustrate cross-sectional views of another semiconductor device with air spacer structures at various stages of its fabrication process, in accordance with some embodiments.

FIG. 10 is a flow diagram of a method for fabricating another semiconductor device with air spacer structures, in accordance with some embodiments.

FIGS. 11A-11L illustrate cross-sectional views of another semiconductor device with air spacer structures at various stages of its fabrication process, in accordance with some embodiments.

FIG. 12 is a flow diagram of a method for fabricating another semiconductor device with air spacer structures, in accordance with some embodiments.

FIGS. 13A-13I illustrate cross-sectional views of another semiconductor device with air spacer structures at various stages of its fabrication process, in accordance with some embodiments.

Illustrative embodiments will now be described with reference to the accompanying drawings. In the drawings, like reference numerals generally indicate identical, functionally similar, and/or structurally similar elements. The discussion of elements with the same annotations applies to each other, unless mentioned otherwise.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The reliability and performance of semiconductor devices (e.g., MOSFETs, finFETs, or GAA FETs) have been negatively impacted by the scaling down of semiconductor devices. The scaling down has resulted in smaller electrical isolation regions (e.g., spacers structures) between gate structures and source/drain (S/D) contact structures. Such smaller electrical isolation regions may not adequately reduce coupling capacitances between the gate structures and the S/D contact structures. Further, the smaller electrical isolation regions may not adequately prevent current leakage between the gate structures and the S/D contact structures, which can lead to degradation of the semiconductor device reliability and performance.

The present disclosure provides example FETs having air spacers and provides example methods of forming such FETs. In some embodiments, a FET can have gate air spacers and contact air spacers. In some embodiments, the gate air spacer can be disposed between a conductive layer of the gate structure and an outer gate spacer. In some embodiments, the contact air spacer can be disposed along sidewalls of the S/D contact structure. The gate air spacers and contact air spacers reduce coupling capacitances between the gate structures and the S/D contact structures. The low dielectric constant of air in the gate air spacers and contact air spacers can reduce the coupling capacitances by about 20% to about 50% compared to FETs without such air spacers. Further, the presence of the gate air spacers and contact air spacers minimizes current leakage paths between the gate structures and the S/D contact structures. Reducing the coupling capacitances and/or current leakage in the FETs can improve the device reliability and performance compared to FETs without the gate air spacers and contact air spacers.

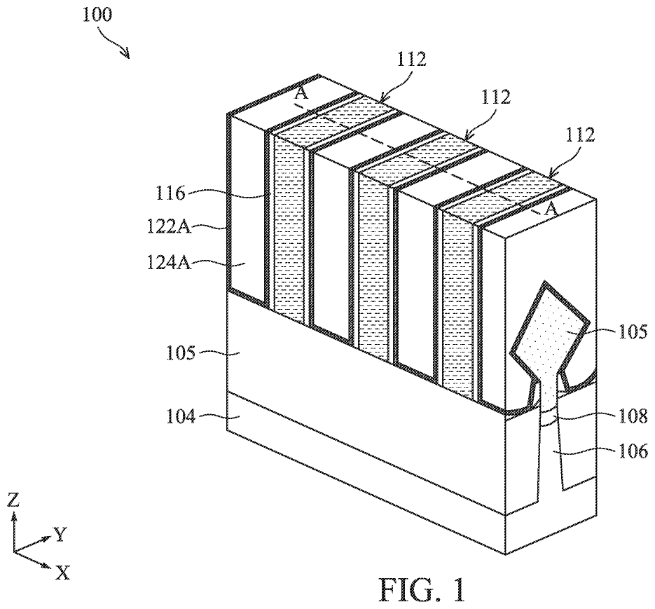

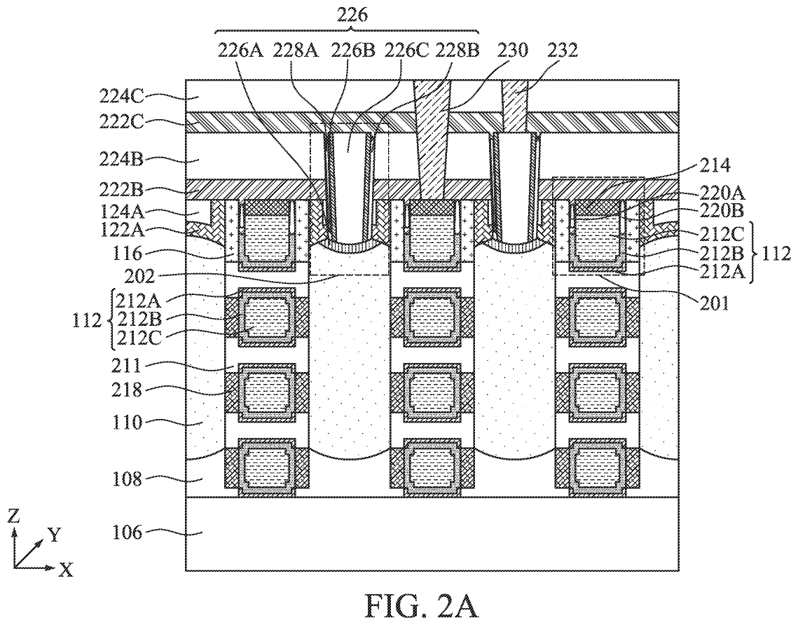

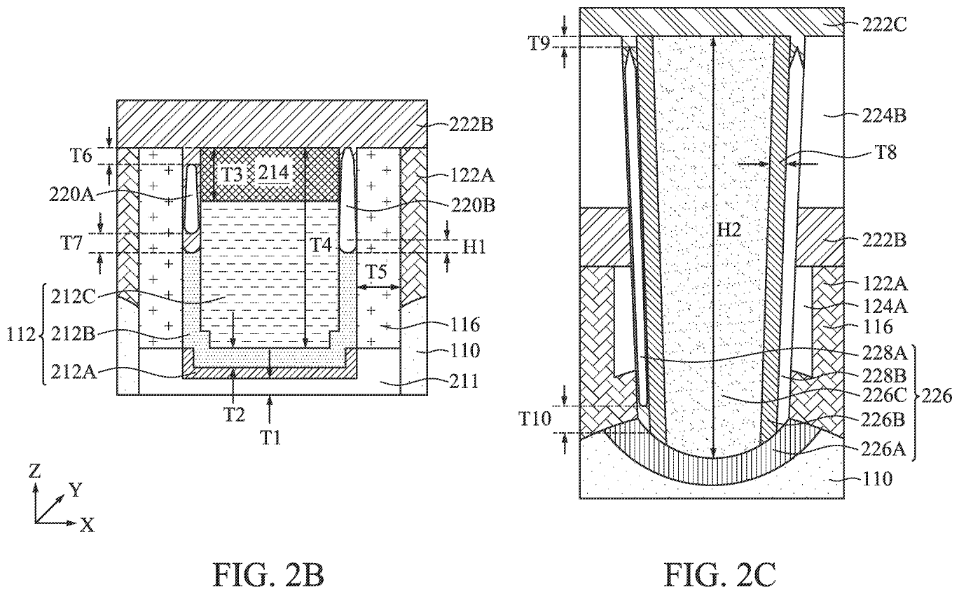

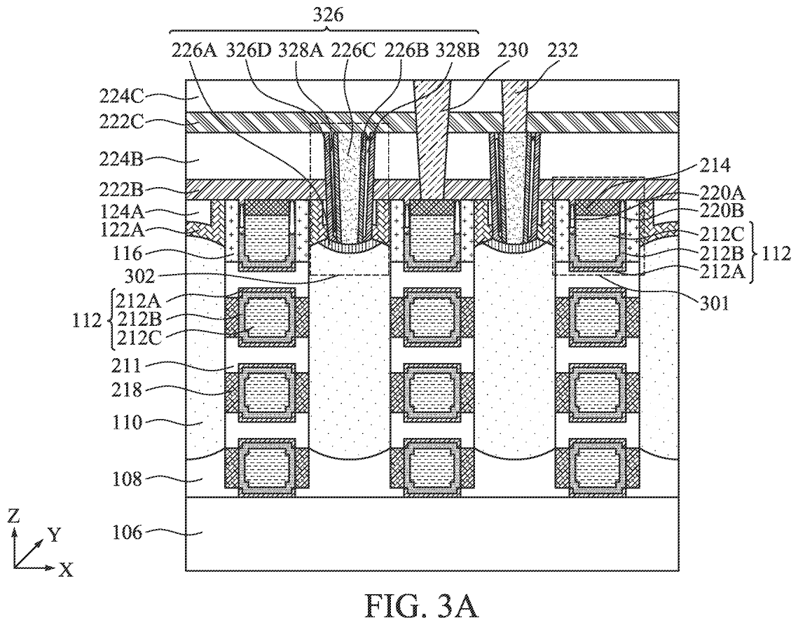

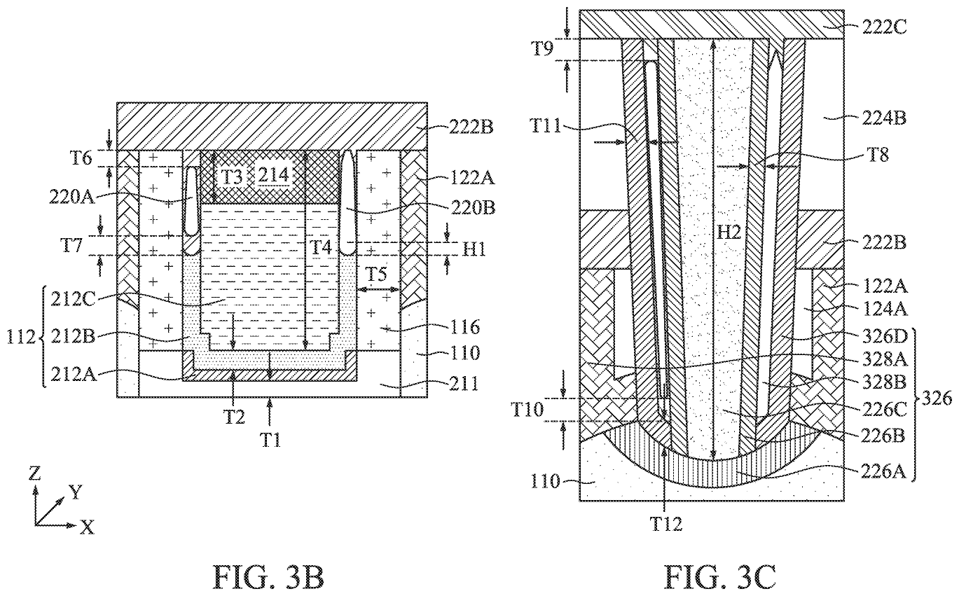

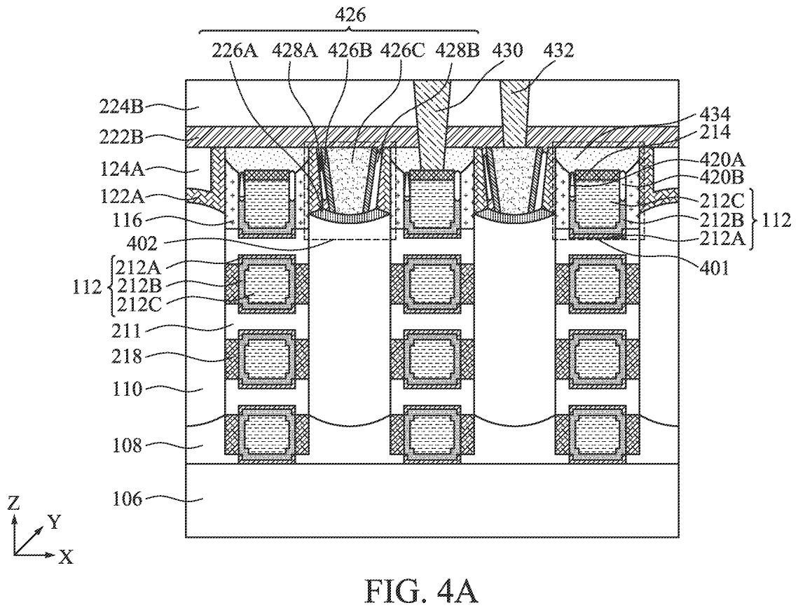

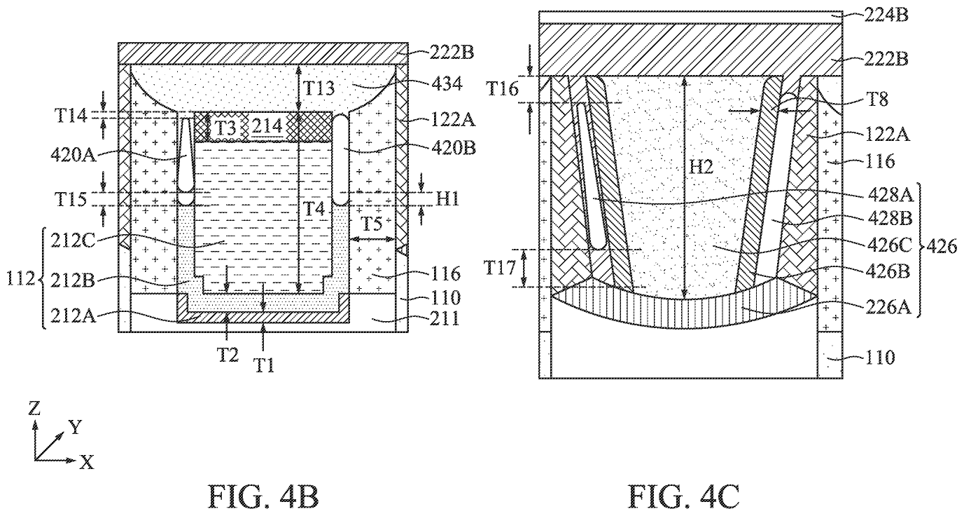

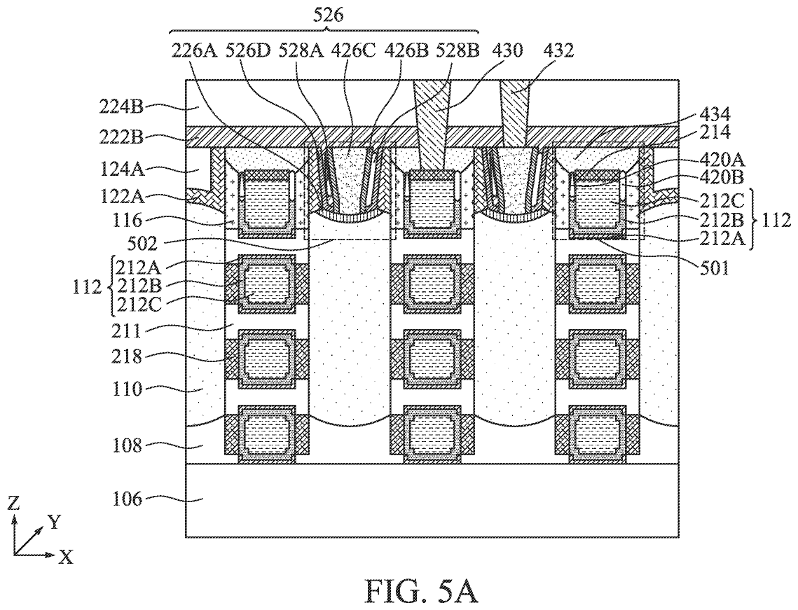

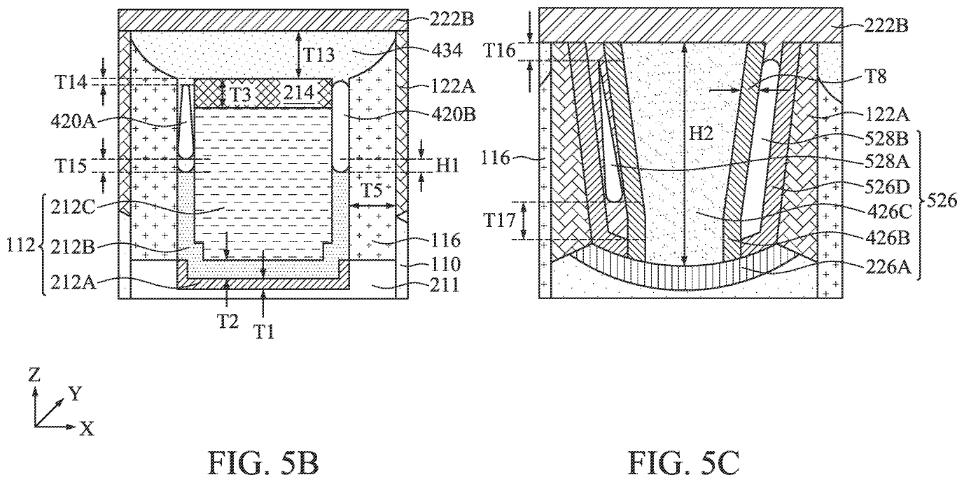

FIG. 1 illustrates an isometric view of a FET 100, according to some embodiments. FIGS. 2A, 3A, 4A, and 5A illustrate different cross-sectional views of FET 100 along line A-A of FIG. 1, according to some embodiments. FIGS. 2B and 2C illustrate enlarged views of regions 201 and 202, respectively, of FIG. 2A, according to some embodiments. FIGS. 3B and 3C illustrate enlarged views of regions 301 and 302, respectively, of FIG. 3A, according to some embodiments. FIGS. 4B and 4C illustrate enlarged views of regions 401 and 402, respectively, of FIG. 4A, according to some embodiments. FIGS. 5B and 5C illustrate enlarged views of regions 501 and 502, respectively, of FIG. 5A, according to some embodiments. FIGS. 2A-5C illustrate views of FET 100 with additional structures that are not shown in FIG. 1 for simplicity. The discussion of elements in FIGS. 1 and 2A-5C with the same annotations applies to each other, unless mentioned otherwise.

Referring to FIGS. 1 and 2A-2C, FET 100 can include (i) a substrate 104, (ii) shallow trench isolation (STI) regions 105 disposed on substrate 104, (iii) a fin structure 106 disposed on substrate 104, (iv) an isolation layer 108 disposed on fin structure 106, (iv) S/D regions 110 disposed on fin structure 106, (v) nanostructured channel regions 211 disposed on fin structure 106, (vi) gate structures 112 surrounding nanostructured channel regions 211, (vii) conductive capping layers 214 disposed on gate structures 112, (viii) outer gate spacers 116, (ix) inner gate spacers 218, (x) gate air spacers 220A and 220B, (xi) etch stop layers (ESLs) 122A, 222B, and 222C, (xii) interlayer dielectric (ILD) layers 124A, 224B, and 224C, (xiii) S/D contact structures 226 disposed on S/D regions 110, (xiv) a gate contact structure 230 disposed on one of gate structures 112, and (xv) a via structure 232 disposed on one of S/D contact structures 226.

In some embodiments, substrate 104 can be a semiconductor material, such as silicon, germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). In some embodiments, fin structure 106 can include a material similar to substrate 104 and extend along an X-axis. In some embodiments, STI region 105, ESLs 122A, 222B, and 222C, and ILD layers 124A, 224B, and 224C can include an insulating material, such as silicon oxide (SiO₂), silicon nitride (SiN), nitrogen-doped silicon carbide (SiCN), silicon oxycarbon nitride (SiOCN), and silicon carbide (SiC).

In some embodiments, isolation layer 108 can be configured to electrically isolate S/D regions 110 from fin structure 106 and substrate 104. Isolation layer 108 can include a dielectric material, such as (i) a doped oxide layer, such as carbon-doped silicon oxide layer, nitrogen-doped silicon oxide layer, and carbon- and nitrogen-doped silicon oxide layer, (ii) a doped carbide layer, such as oxygen-doped silicon carbide layer, nitrogen-doped silicon carbide layer, and oxygen- and nitrogen-doped silicon carbide layer, (iii) a doped nitride layer, such as oxygen-doped silicon nitride layer, carbon-doped silicon nitride layer, and oxygen- and carbon-doped silicon nitride layer, and (iv) an undoped silicon nitride layer.

In some embodiments, isolation layer 108 can include a doped oxide, carbide, or nitride layer with a carbon concentration of about 1 atomic % to about 25 atomic % and a nitrogen concentration of about 1 atomic % to about 30 atomic %. In some embodiments, isolation layer 108 can include a doped oxide, carbide, or nitride layer with a carbon-to-nitrogen concentration ratio of about 0.2 to about 2. Within these concentration ranges of carbon and nitrogen, isolation layer 108 can have a density of about 1.5 gm/cm³ to about 3 gm/cm³ and a dielectric constant of about 2 to about 5. If the density is less than 1.5 gm/cm³, isolation layer 108 may be damaged (e.g., etched) during subsequent processing (e.g., etching processes). On the other hand, if the density is greater than 3 gm/cm³, the dielectric constant of isolation layer 108 may be greater than 5, which can increase parasitic capacitance of FET 100 and degrade device performance. In some embodiments, the density range of about 1.5 gm/cm³ to about 3 gm/cm³ can keep fluorine contaminants in isolation layer 108 from processing chemicals (e.g., etchants) to a concentration less than about 2 atomic % (e.g., about 0 atomic % to about 1.9 atomic %).

In some embodiments, isolation layer 108 can have a top surface with a curved profile, as shown in FIGS. 1 and 2A or can have a top surface with a substantially planar profile (not shown). In some embodiments, isolation layer 108 can have a thickness along a Z-axis of about 5 nm to about 15 nm. Within this thickness range, adequate electrical isolation can be provided by isolation layer 108 between S/D regions 110 and fin structure 106 without compromising the size and manufacturing cost of FET 100.

In some embodiments, for NFET 100, each of S/D regions 110 can include an epitaxially-grown semiconductor material, such as Si, and n-type dopants, such as phosphorus and other suitable n-type dopants. In some embodiments, for PFET 100, each of S/D regions 110 can include an epitaxially-grown semiconductor material, such as Si and SiGe, and p-type dopants, such as boron and other suitable p-type dopants.

In some embodiments, nanostructured channel regions 211 can include semiconductor materials similar to or different from substrate 104. In some embodiments, nanostructured channel regions 211 can include Si, SiAs, silicon phosphide (SiP), SiC, SiCP, SiGe, Silicon Germanium Boron (SiGeB), Germanium Boron (GeB), Silicon-Germanium-Tin-Boron (SiGeSnB), a III-V semiconductor compound, or other suitable semiconductor materials. Though rectangular cross-sections of nanostructured channel regions 211 are shown, nanostructured channel regions 211 can have cross-sections of other geometric shapes (e.g., circular, elliptical, triangular, or polygonal). As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. In some embodiments, nanostructured channel regions 211 can have be in the form of nanosheets, nanowires, nanorods, nanotubes, or other suitable nanostructured shapes.

In some embodiments, gate structures 112 can be multi-layered structures and can surround each of nanostructured channel regions 211 for which gate structures 112 can be referred to as “gate-all-around (GAA) structures.” FET 100 can be referred to as “GAA FET 100.” In some embodiments, FET 100 can be a finFET and have fin regions (not shown) instead of nanostructured channel regions 211.

In some embodiments, each of gate structures 112 can include (i) an interfacial oxide (IL) layer 212A disposed on nanostructured channel regions 211, (ii) a high-k gate dielectric layer 212B disposed on IL layer 212A, and (iii) a conductive layer 212C disposed on high-k gate dielectric layer 212B. In some embodiments, IL layer 212A can include silicon oxide (SiO₂), silicon germanium oxide (SiGeOₓ), or germanium oxide (GeOₓ). In some embodiments, high-k gate dielectric layer 212B can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), zirconium aluminum oxide (ZrAlO), zirconium silicate (ZrSiO₂), lanthanum oxide (La₂O₃), aluminum oxide (Al₂O₃) zinc oxide (ZnO), hafnium zinc oxide (HfZnO), and yttrium oxide (Y₂O₃). In some embodiments, IL layer 212A can have a thickness T1 of about 0.1 nm to about 2 nm and high-k gate dielectric layer 212B can have a thickness T2 of about 0.5 nm to about 5 nm. Within these ranges of thicknesses T1 and T2, gate structures 112 can perform adequately without compromising the size and manufacturing cost of FET 100.

In some embodiments, conductive layer 212C can be a multi-layered structure. The different layers of conductive layer 212C are not shown for simplicity. Each of conductive layer 212C can include a work function metal (WFM) layer disposed on high-k gate dielectric layer 212B and a gate metal fill layer disposed on the WFM layer. In some embodiments, the WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for GAA NFET 100. In some embodiments, the WFM layer can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for GAA PFET 100. The gate metal fill layers can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof.

Conductive capping layers 214 provide conductive interfaces between conductive layer 212C and gate contact structure 230 to electrically connect conductive layer 212C to gate contact structure 230 without forming gate contact structure 230 directly on or within conductive layer 212C. Gate contact structure 230 is not formed directly on or within conductive layer 212C to prevent contamination by any of the processing materials used in the formation of gate contact structure 230. Contamination of conductive layer 212C can lead to the degradation of device performance. Thus, with the use of conductive capping layers 214, gate structure 112 can be electrically connected to gate contact structure 230 without compromising the integrity of gate structure 112.

In some embodiments, conductive capping layer 214 can have a thickness T3 of about 1 nm to about 8 nm for adequately providing a conductive interface between conductive layer 212C and gate contact structure 230 without compromising the size and manufacturing cost of FET 100. In some embodiments, the total thickness T4 of conductive capping layer 214 and conductive layer 212C can range from about 10 nm to about 30 nm. In some embodiments, conductive capping layer 214 can include a metallic material, such as tungsten (W), ruthenium (Ru), molybdenum (Mo), cobalt (Co), other suitable metallic materials, and a combination thereof. In some embodiments, conductive capping layer 214 can be formed using a precursor gas of tungsten pentachloride (WCl₅) or tungsten hexachloride (WCl₆), and as a result, conductive capping layer 214 can include tungsten with impurities of chlorine atoms. The concentration of chlorine atom impurities can range from about 1 atomic percent to about 10 atomic percent of the total concentration of atoms in each conductive capping layer 214.

In some embodiments, gate structure 112 can be electrically isolated from adjacent S/D contact structure 226 by outer gate spacers 116 and the portions of gate structures 112 surrounding nanostructured channel regions 211 can be electrically isolated from adjacent S/D regions 110 by inner gate spacers 218. Outer gate spacers 116 and inner gate spacers 218 can include a material similar to or different from each other. In some embodiments, outer gate spacers 116 and inner gate spacers 218 can include an insulating material, such as silicon oxide, silicon oxide (SiO₂), silicon nitride (SiN), nitrogen-doped silicon carbide (SiCN), silicon oxycarbon nitride (SiOCN), and silicon carbide (SiC). In some embodiments, each of outer gate spacers 116 can have a thickness T5 of about 1 nm to about 10 nm. Within this range of thickness T5, adequate electrical isolation can be provided by outer gate spacers 116 between gate structures 112 and adjacent S/D contact structures 226 without compromising the size and manufacturing cost of FET 100.

In some embodiments, additional electrical isolation between gate structures 112 and adjacent S/D contact structures 226 can be provided by gate air spacers 220A and 220B. Besides providing electrical isolation between gate structures 112 and adjacent S/D contact structures 226, coupling capacitances can also be substantially reduced between gate structures 112 and adjacent S/D contact structures 226 with the use of gate air spacers 220A and 220B. The coupling capacitances can negatively impact the speed of electrical signals in FET 100. Thus, reducing the coupling capacitances between gate structures 112 and adjacent S/D contact structures 226 can improve the performance of FET 100.

In each gate structure 112, gate air spacers 220A and 220B can be disposed on high-k gate dielectric layer 212B, between conductive layer 212C and outer gate spacer 116, and between conductive capping layer 214 and outer gate spacer 116. In some embodiments, gate air spacers 220A and 220B can have cross-sectional profiles similar to or different from each other. In some embodiments, gate air spacer 220A can have a cross-sectional profile shown in FIG. 2B, or that of gate air spacer 220B shown in FIG. 2B, and vice versa. In some embodiments, both gate air spacers 220A and 220B can have cross-sectional profiles of gate air spacer 220A shown in FIG. 2B or can have cross-sectional profiles of gate air spacer 220B shown in FIG. 2B. In some embodiments, gate air spacers 220A and 220B can have tapered cross-sectional profiles (shown in FIGS. 2A and 2B), rectangular-shaped cross-sectional profiles (not shown), oval-shaped cross-sectional profiles (not shown), triangular-shaped cross-sectional profiles (not shown), or other geometric-shaped cross-sectional profiles.

In some embodiments, the widest portions of gate air spacers 220A and 220B can have widths of about 1.5 nm to about 3 nm along an X-axis. In some embodiments, gate air spacers 220A and 220B can be formed with a curved bottom profile, which forms a curved top surface profile in high-k gate dielectric layer 212B. A height H1 between the edge and the center of the curved top surface profile can be about 1 nm to about 3 nm, which can depend on the fabrication process (e.g., etching process) of gate air spacers 220A and 220B. In some embodiments, gate air spacer 220A can be surrounded on all sides by a first portion of ESL 222B, which extends below top surfaces of outer gate spacers 116, as shown in FIG. 2B. In some embodiments, a top portion of gate air spacer 220B can be surrounded by a second portion of ESL 222B, which extends below the top surfaces of outer gate spacers 116, as shown in FIG. 2B. In some embodiments, the first portion of ESL 222B can have a thickness T6 of about 1 nm to about 8 nm disposed on gate air spacer 220A and can have a thickness T7 of about 1 nm to about 8 nm disposed below gate air spacer 220A. In some embodiments, the first and second portions of ESL 222B can have a thickness of about 0.1 nm to about 2 nm along sidewalls of gate air spacers 220A and 220B. Within the above mentioned ranges of widths, height H1, and thicknesses T6 and T7, gate air spacers 220A and 220B can substantially reduce coupling capacitances between gate structures 112 and adjacent S/D contact structures 226 without compromising the size and manufacturing cost of FET 100.

In some embodiments, each of S/D contact structures 226 can include (i) a silicide layer 226A, (ii) diffusion barrier layers 226B (also referred to as “liners 226B”) disposed on silicide layer 226A, (iii) a contact plug 226C disposed on silicide layer 226A, (iv) contact air spacers 228A and 228B. In some embodiments, silicide layer 226A can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), other suitable metal silicide materials, or a combination thereof for GAA NFET 100. In some embodiments, silicide layer 226A can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof for GAA PFET 100.

Diffusion barrier layers 226B can prevent the oxidation of contact plugs 226C by preventing the diffusion of oxygen atoms from adjacent structures (e.g., ESLs 122A and 222B and ILD layers 124A and 224B) to contact plugs 226C. In some embodiments, diffusion barrier layers 226B can include a dielectric nitride or carbide material, such as silicon nitride (SixNy), silicon oxynitride (SiON), silicon carbon nitride (SiCN), silicon carbide (SiC), silicon carbon oxynitride (SiCON), and other suitable dielectric nitride or carbide materials. In some embodiments, diffusion barrier layers 226B can have a thickness T8 of about 1.5 nm to about 4 nm. Within this range of thickness T8, diffusion barrier layer 226B can adequately prevent the oxidation of contact plugs 226C without compromising the size and manufacturing cost of FET 100.

In some embodiments, contact plugs 226C can include conductive materials with low resistivity (e.g., resistivity of about 50 μΩ-cm, about 40 μΩ-cm, about 30 μΩ-cm, about 20 μΩ-cm, or about 10 μΩ-cm), such as cobalt (Co), tungsten (W), ruthenium (Ru), iridium (Ir), nickel (Ni), Osmium (Os), rhodium (Rh), aluminum (Al), molybdenum (Mo), other suitable conductive materials with low resistivity, and a combination thereof. In some embodiments, contact plugs 226C can have a height H2 of about 15 nm to about 40 nm. Within this range of height H2, contact plugs 226C can provide adequate electrical conductivity between S/D regions 110 and overlying interconnect structures (not shown) without compromising the size and manufacturing cost of FET 100.

In some embodiments, diffusion barrier layers 226B and contact plugs 226C vertically extend from top surfaces of silicide layer 226A and to a bottom surface of ESL 222C, and through ESL 122A, ILD layer 124A, ESL 222B, and ILD layer 224B. Bottom surfaces of diffusion barrier layers 226B and contact plugs 226C can be in physical contact with the top surfaces of silicide layer 226A and top surfaces of diffusion barrier layers 226B and contact plugs 226C can be in physical contact with the bottom surface of ESL 222C.

In some embodiments, contact air spacers 228A and 228B can be disposed on silicide layer 226A and along outer sidewalls of diffusion barrier layers 226B. In some embodiments, contact air spacers 228A and 228B vertically extend between top surfaces of silicide layer 226A and a bottom surface of ESL 222C, and through ESL 122A, ILD layer 124A, ESL 222B, and ILD layer 224B. Similar to gate air spacers 220A and 220B, contact air spacers 228A and 228B can substantially reduce coupling capacitances between S/D contact structures 226 and adjacent gate structures 112. With the use of both contact air spacers 228A and 228B and gate air spacers 220A and 220B, the coupling capacitances between S/D contact structures 226 and adjacent gate structures 112 can be substantially minimized in FET 100.

In some embodiments, contact air spacers 228A and 228B can have cross-sectional profiles similar to or different from each other. In some embodiments, contact air spacer 228A can have a cross-sectional profile shown in FIG. 2C, or that of contact air spacer 228B shown in FIG. 2C, and vice versa. In some embodiments, both contact air spacers 228A and 228B can have cross-sectional profiles of contact air spacer 228A shown in FIG. 2C or can have cross-sectional profiles of contact air spacer 228B shown in FIG. 2C. In some embodiments, contact air spacers 228A and 228B can have tapered cross-sectional profiles (shown in FIGS. 2A and 2C), rectangular-shaped cross-sectional profiles (not shown), oval-shaped cross-sectional profiles (not shown), triangular-shaped cross-sectional profiles (not shown), or other geometric-shaped cross-sectional profiles.

In some embodiments, top and bottom ends of contact air spacers 228A and 228B can have curved profiles and different widths. In some embodiments, the widest portions of contact air spacers 228A and 228B can have widths of about 1.5 nm to about 3 nm along an X-axis. In some embodiments, contact air spacer 228A can be surrounded on all sides by a first portion of ESL 222C, which extends below a top surface of ILD layer 224B, as shown in FIG. 2B. In some embodiments, a top portion of contact air spacer 228B can be surrounded by a second portion of ESL 222C, which extends below the top surface of ILD layer 224B, as shown in FIG. 2B. In some embodiments, the first portion of ESL 222C can have a thickness T9 of about 1 nm to about 8 nm disposed on contact air spacer 228A and can have a thickness T10 of about 1 nm to about 8 nm disposed below contact air spacer 228A. In some embodiments, the first portions of ESL 222C can have a thickness of about 0.1 nm to about 2 nm along sidewalls of contact air spacer 228A. Within the above mentioned ranges of widths, and thicknesses T9 and T10, contact air spacers 228A and 228B can substantially reduce coupling capacitances between S/D contact structures 226 and adjacent gate structures 112 without compromising the size and manufacturing cost of FET 100.

Gate contact structure 230 can be disposed on and in physical contact with one of conductive capping layers 214. In some embodiments, gate contact structure 230 can vertically extend through ESL 222B, ILD layer 224B, ESL 222C, and ILD layer 224C. Via structure 232 can be disposed on and in physical contact with one of S/D contact structures 226. In some embodiments, via structure 232 can vertically extend through ESL 222C and ILD layer 224C. In some embodiments, top surfaces of gate contact structure 230 and via structure 232 can be substantially coplanar with a top surface of ILD layer 224C. In some embodiments, gate contact structure 230 and via structure 232 can include a metallic material, such as tungsten (W), ruthenium (Ru), molybdenum (Mo), cobalt (Co), other suitable metallic materials, and a combination thereof. In some embodiments, conductive capping layers 214, contact plugs 226C, gate contact structure 230, and via structure 232 can have a metallic material similar to or different from each other.

Referring to FIGS. 3A-3C, the discussion of the cross-sectional views of FIGS. 2A-2C applies to the cross-sectional views of FIGS. 3A-3C, unless mentioned otherwise. The discussion of elements in FIGS. 1 and 2A-3C with the same annotations applies to each other, unless mentioned otherwise. In some embodiments, FET 100 can include S/D contact structures 326, instead of S/D contact structures 226 of FIGS. 2A and 2C. Each of S/D contact structures 326 can include (i) a silicide layer 226A, (ii) diffusion barrier layers 226B, (iii) a contact plug 226C, (iv) contact air spacers 328A and 328B, and (v) dielectric liners 326D.

In some embodiments, dielectric liners 326D can include a dielectric nitride or carbide material, such as silicon nitride (SixNy), silicon oxynitride (SiON), silicon carbon nitride (SiCN), silicon carbide (SiC), silicon carbon oxynitride (SiCON), and other suitable dielectric nitride or carbide materials. In some embodiments, dielectric liners 326D can have a sidewall thickness T11 of about 1.5 nm to about 4 nm and a bottom thickness T12 of about 1.5 nm to about 4 nm. Within these ranges of thicknesses T11 and T12, dielectric liners 326D along with diffusion barrier layers 226B can adequately protect underlying structures during the fabrication (e.g., etching process) of contact air spacers 328A and 328B without compromising the size and manufacturing cost of FET 100. In some embodiments, dielectric liners 326D can vertically extend from top surfaces of silicide layer 226A and to a bottom surface of ESL 222C, and through ESL 122A, ILD layer 124A, ESL 222B, and ILD layer 224B. Bottom surfaces of dielectric liners 326D can be in physical contact with the top surfaces of silicide layer 226A and top surfaces of dielectric liners 326D can be in physical contact with the bottom surface of ESL 222C.

The discussion of contact air spacers 228A and 228B applies to contact air spacers 328A and 328B, respectively, unless mentioned otherwise. In some embodiments, each of contact air spacers 328A and 328B can be disposed on a bottom portion of dielectric liner 326D and between adjacent pairs of dielectric liner 326D and diffusion barrier layer 226B. Similar to contact air spacers 228A and 228B, contact air spacers 328A and 328B can substantially reduce coupling capacitances between S/D contact structures 226 and adjacent gate structures 112. With the use of both contact air spacers 328A and 328B and gate air spacers 220A and 220B, the coupling capacitances between S/D contact structures 326 and adjacent gate structures 112 can be substantially minimized in FET 100.

Referring to FIGS. 4A-4C, the discussion of the cross-sectional views of FIGS. 2A-2C applies to the cross-sectional views of FIGS. 4A-4C, unless mentioned otherwise. The discussion of elements in FIGS. 1, 2A-2C, and 4A-4C with the same annotations applies to each other, unless mentioned otherwise. In some embodiments, FET 100 can additionally include insulating capping layers 434 and may not include ESL 222C and ILD layer 224C. In some embodiments, FET 100 can include (i) S/D contact structures 426, instead of S/D contact structures 226, (ii) gate contact structure 430, instead of gate structure 230, and (iii) via structure 432, instead of via structure 232.

In some embodiments, insulating capping layers 434 can be disposed on conductive capping layers 214, outer gate spacers 116, and gate air spacers 420A and 420B. Insulating capping layers 434 can protect the underlying conductive capping layers 214 from structural and/or compositional degradation during subsequent processing of FET 100. In some embodiments, insulating capping layers 434 can include a dielectric nitride or carbide material, such as silicon nitride (SixNy), silicon oxynitride (SiON), silicon carbon nitride (SiCN), silicon carbide (SiC), silicon carbon oxynitride (SiCON), and other suitable dielectric nitride or carbide materials. In some embodiments, insulating capping layers 434 can have a thickness T13 of about 5 nm to about 10 nm for adequate protection of the underlying conductive capping layers 214 without compromising the size and manufacturing cost of FET 100. Insulating capping layers 434 can serve the function of ESL 222B and ILD layer 224B shown in FIG. 2A. As a result, ESL 222B and ILD layer 224B of FIG. 4A can serve the function of ESL 222C and ILD layer 224C shown in FIG. 2A, and ESL 222C and ILD layer 224C may not be formed in FET 100 of FIG. 4A.

Similar to gate air spacers 220A and 220B, gate air spacers 420A and 420B substantially reduce coupling capacitances between gate structures 112 and adjacent S/D contact structures 426. The discussion of gate air spacers 220A and 220B applies to gate air spacers 420A and 420B, respectively, unless mentioned otherwise. In some embodiments, the widest portions of gate air spacers 420A and 420B can have widths of about 1.5 nm to about 3 nm along an X-axis. In some embodiments, gate air spacer 420A can be surrounded on all sides by a first portion of insulating capping layer 434, which extends below top surfaces of outer gate spacers 116, as shown in FIG. 4B. In some embodiments, a top portion of gate air spacer 420B can be surrounded by a second portion of insulating capping layer 434, which extends below the top surfaces of outer gate spacers 116, as shown in FIG. 4B. In some embodiments, the first portion of insulating capping layer 434 can have a thickness T14 of about 1 nm to about 8 nm disposed on gate air spacer 420A and can have a thickness T15 of about 1 nm to about 8 nm disposed below gate air spacer 420A. In some embodiments, the first and second portions of insulating capping layer 434 can have a thickness of about 0.1 nm to about 2 nm along sidewalls of gate air spacers 420A and 420B. Within the above mentioned ranges of widths and thicknesses T14 and T15, gate air spacers 420A and 420B can substantially reduce coupling capacitances between gate structures 112 and adjacent S/D contact structures 426 without compromising the size and manufacturing cost of FET 100.

In some embodiments, each of S/D contact structures 426 can include (i) a silicide layer 226A, (ii) diffusion barrier layers 426B (also referred to as “liners 426B”) disposed on silicide layer 226A, (iii) a contact plug 426C disposed on silicide layer 426A, and (iv) contact air spacers 428A and 428B. The discussion of diffusion barrier layers 226B and contact plugs 226C applies to diffusion barrier layers 426B and contact plugs 426C, respectively, unless mentioned otherwise. In some embodiments, diffusion barrier layers 426B and contact plugs 426C can vertically extend from top surfaces of silicide layer 226A and to a bottom surface of ESL 222B, and through ESL 122A and ILD layer 124A. Bottom surfaces of diffusion barrier layers 426B and contact plugs 426C can be in physical contact with the top surfaces of silicide layer 226A and top surfaces of diffusion barrier layers 426B and contact plugs 426C can be in physical contact with the bottom surface of ESL 222B.

Similar to contact air spacers 228A and 228B, contact air spacers 428A and 428B substantially reduce coupling capacitances between S/D contact structures 426 and adjacent gate structures 112. The discussion of contact air spacers 228A and 228B applies to contact air spacers 428A and 428B, respectively, unless mentioned otherwise. In some embodiments, contact air spacers 428A and 428B can vertically extend between top surfaces of silicide layer 226A and a bottom surface of ESL 222B, and through ESL 122A and ILD layer 124A. In some embodiments, the widest portions of contact air spacers 428A and 428B can have widths of about 1.5 nm to about 3 nm along an X-axis. In some embodiments, contact air spacer 428A can be surrounded on all sides by a first portion of ESL 222B, which extends below a top surface of ESL 122A, as shown in FIG. 4B. In some embodiments, a top portion of contact air spacer 428B can be surrounded by a second portion of ESL 222B, which extends below the top surface of ESL 122A, as shown in FIG. 4B. In some embodiments, the first portion of ESL 222B can have a thickness T16 of about 1 nm to about 8 nm disposed on contact air spacer 428A and can have a thickness T17 of about 1 nm to about 8 nm disposed below contact air spacer 428A. In some embodiments, the first portions of ESL 222B can have a thickness of about 0.1 nm to about 2 nm along sidewalls of contact air spacer 428A. Within the above mentioned ranges of widths, and thicknesses T16 and T17, contact air spacers 428A and 428B can substantially reduce coupling capacitances between S/D contact structures 426 and adjacent gate structures 112 without compromising the size and manufacturing cost of FET 100.

The discussion of gate contact structure 230 and via structure 232 applies to gate contact structure 430 and via structure 432, respectively, unless mentioned otherwise. In some embodiments, gate contact structure 230 can vertically extend through insulating capping layers 434, ESL 222B, and ILD layer 224B. Via structure 432 can be disposed on and in physical contact with one of S/D contact structures 426. In some embodiments, via structure 432 can vertically extend through ESL 222B and ILD layer 224B. In some embodiments, top surfaces of gate contact structure 430 and via structure 432 can be substantially coplanar with a top surface of ILD layer 224B.

Referring to FIGS. 5A-5C, the discussion of the cross-sectional views of FIGS. 4A-4C applies to the cross-sectional views of FIGS. 5A-5C, unless mentioned otherwise. The discussion of elements in FIGS. 1 and 2A-5C with the same annotations applies to each other, unless mentioned otherwise. In some embodiments, FET 100 can include S/D contact structures 526, instead of S/D contact structures 426 of FIGS. 4A and 4C. Each of S/D contact structures 526 can include (i) a silicide layer 226A, (ii) diffusion barrier layers 426B, (iii) a contact plug 426C, (iv) contact air spacers 528A and 528B, and (v) dielectric liners 526D.

The discussion of dielectric liners 326D applies to dielectric liners 526D unless mentioned otherwise. In some embodiments, dielectric liners 526D can vertically extend from top surfaces of silicide layer 226A and to a bottom surface of ESL 222B and through ESL 122A and ILD layer 124A. Bottom surfaces of dielectric liners 526D can be in physical contact with the top surfaces of silicide layer 226A and top surfaces of dielectric liners 526D can be in physical contact with the bottom surface of ESL 222B.

The discussion of contact air spacers 428A and 428B applies to contact air spacers 528A and 528B, respectively, unless mentioned otherwise. In some embodiments, each of contact air spacers 528A and 528B can be disposed on a bottom portion of dielectric liner 526D and between adjacent pairs of dielectric liner 526D and diffusion barrier layer 426B. With the use of both contact air spacers 528A and 528B and gate air spacers 420A and 420B, the coupling capacitances between S/D contact structures 526 and adjacent gate structures 112 can be substantially minimized in FET 100.

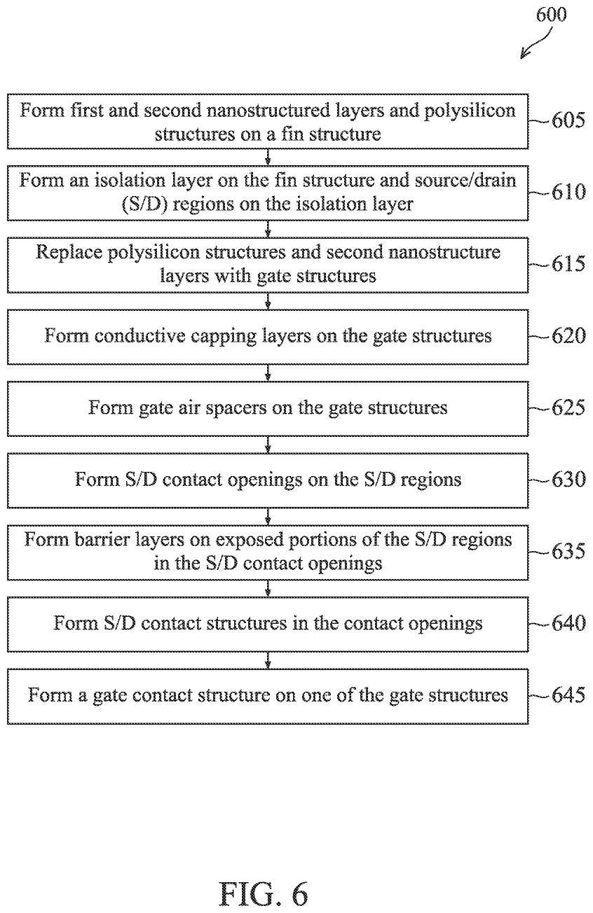

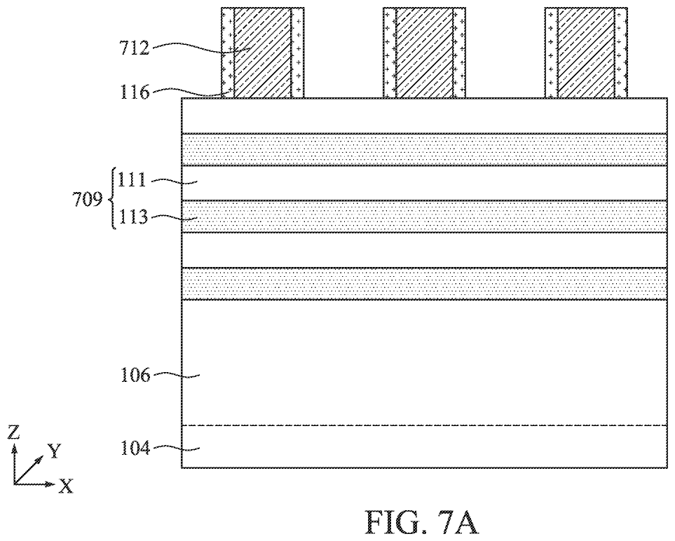

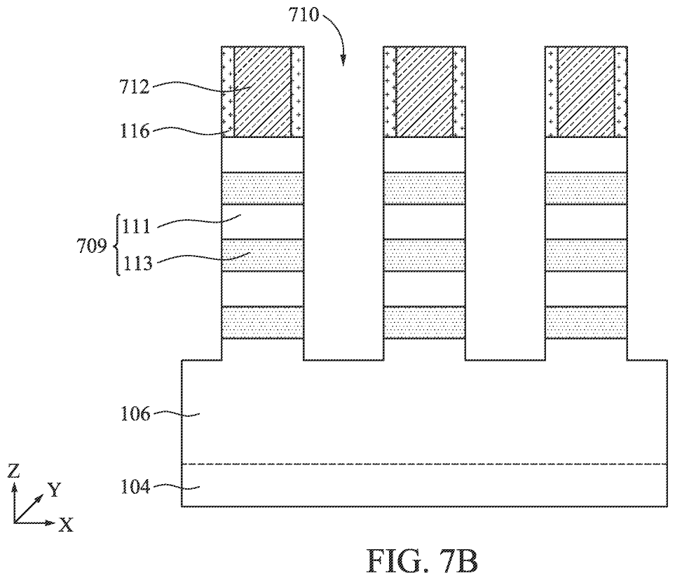

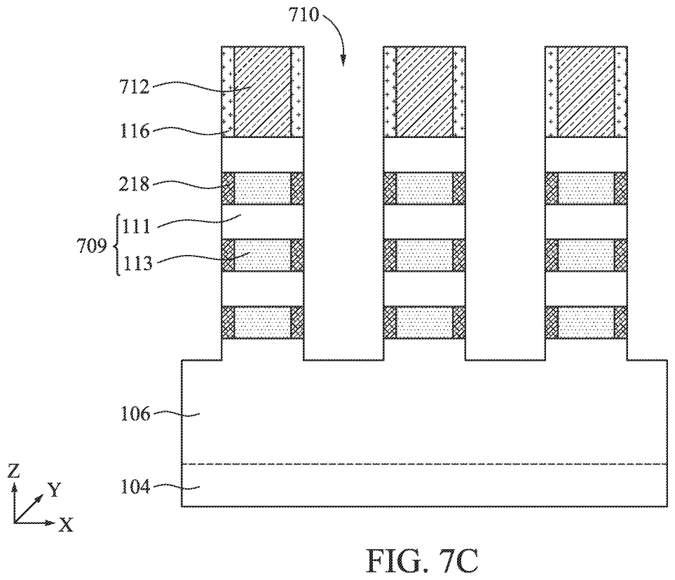

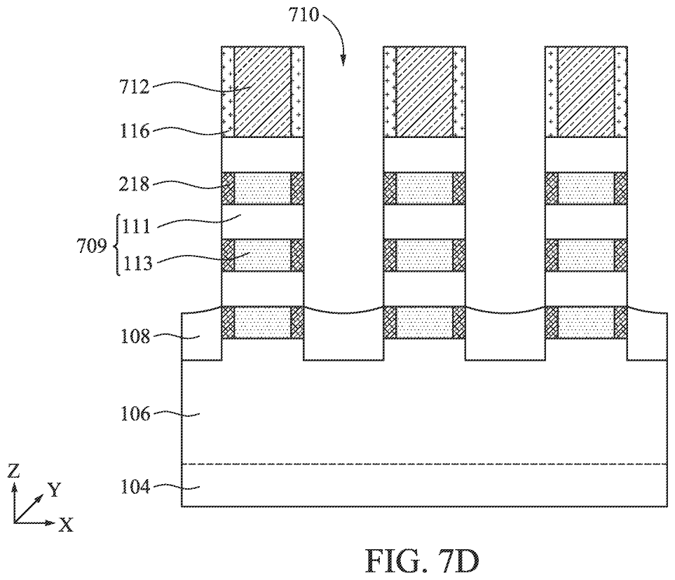

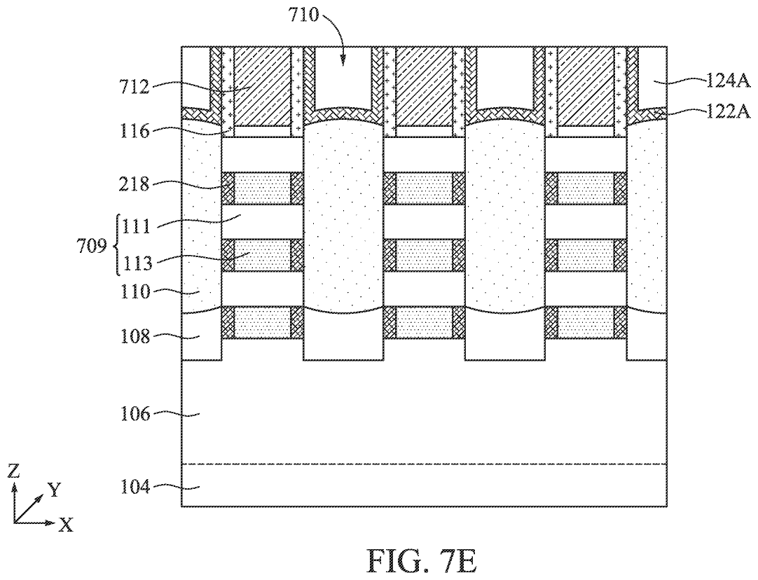

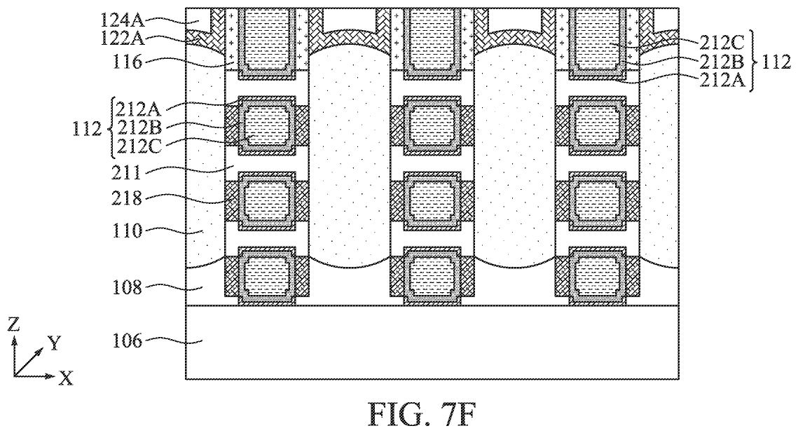

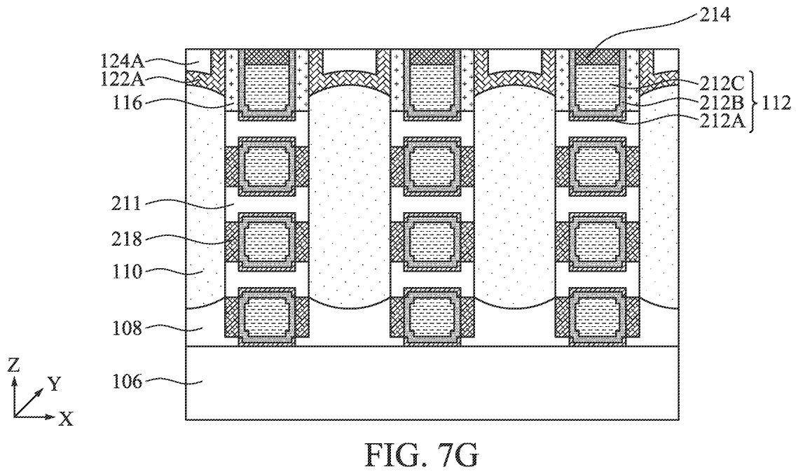

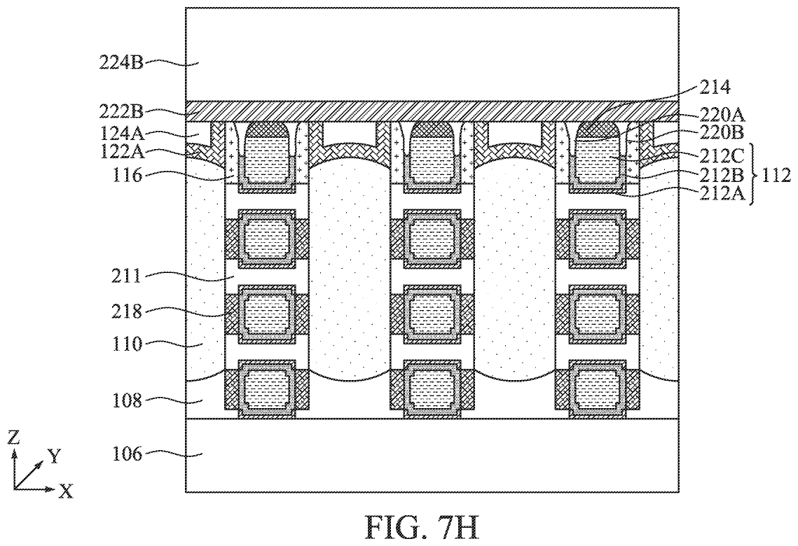

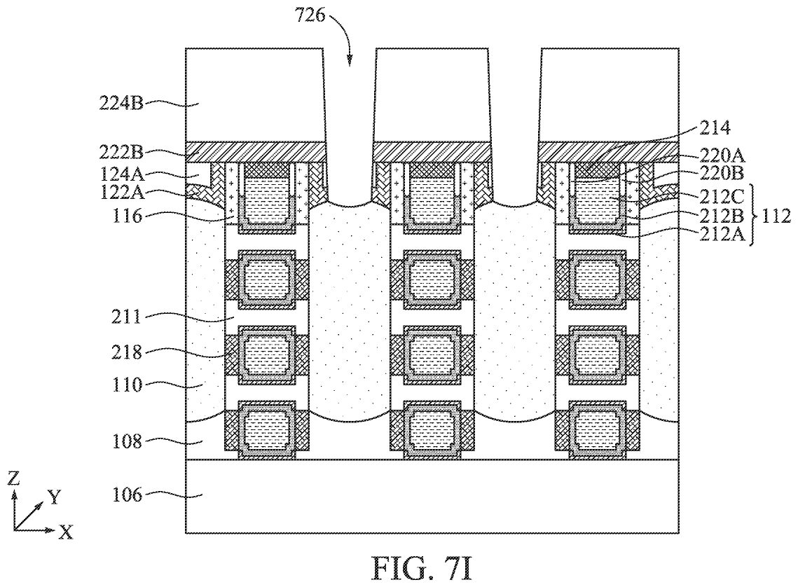

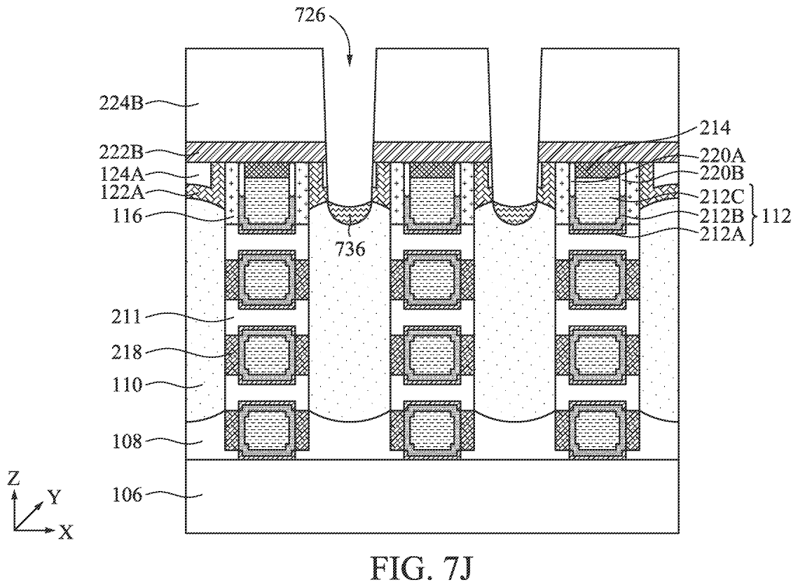

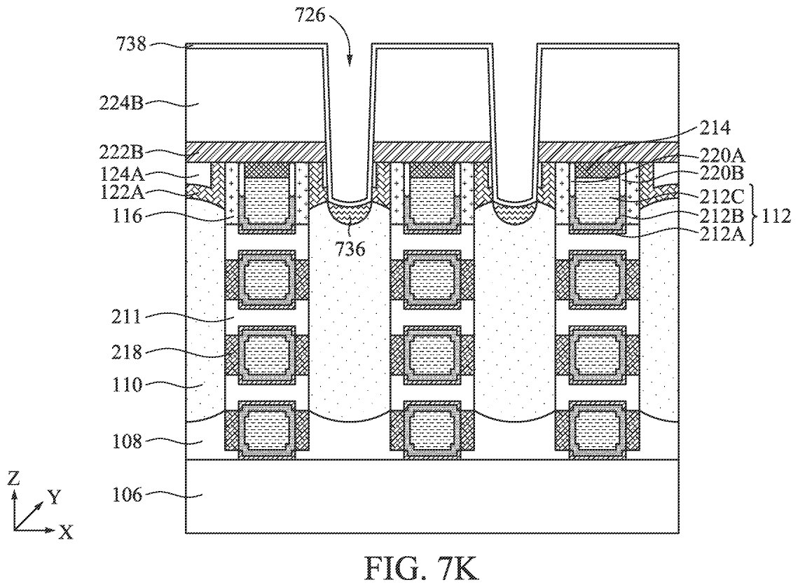

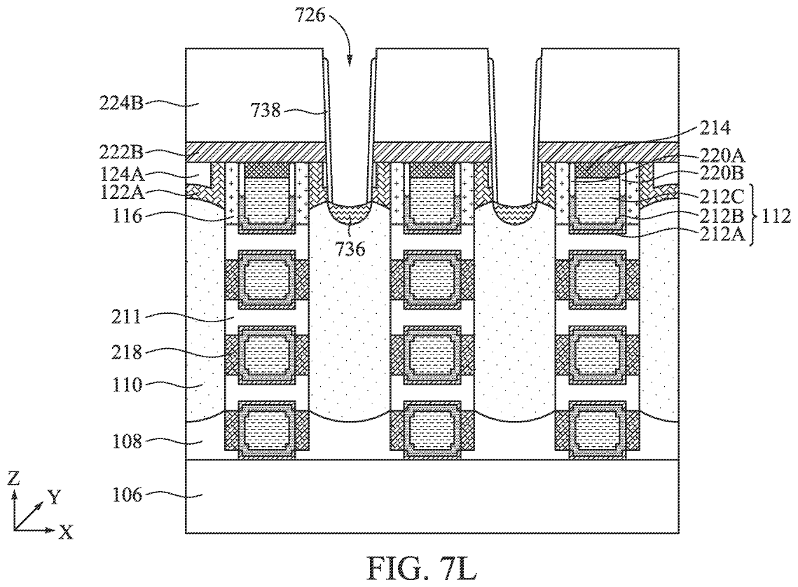

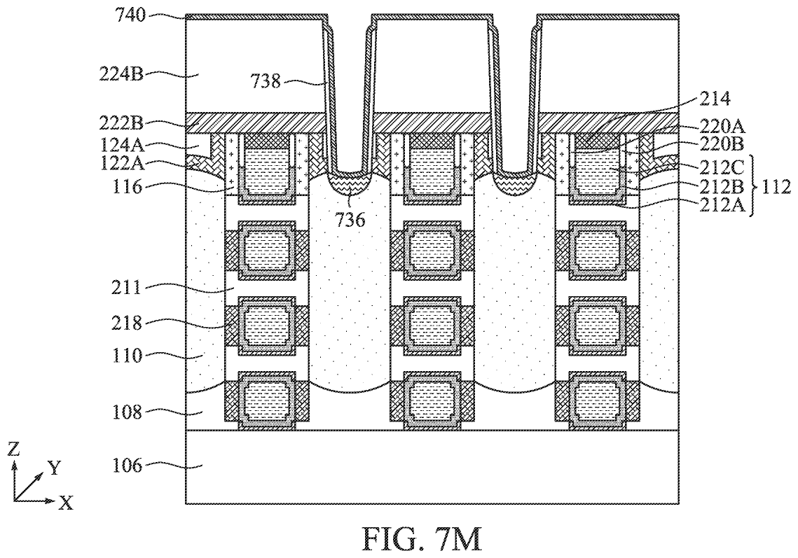

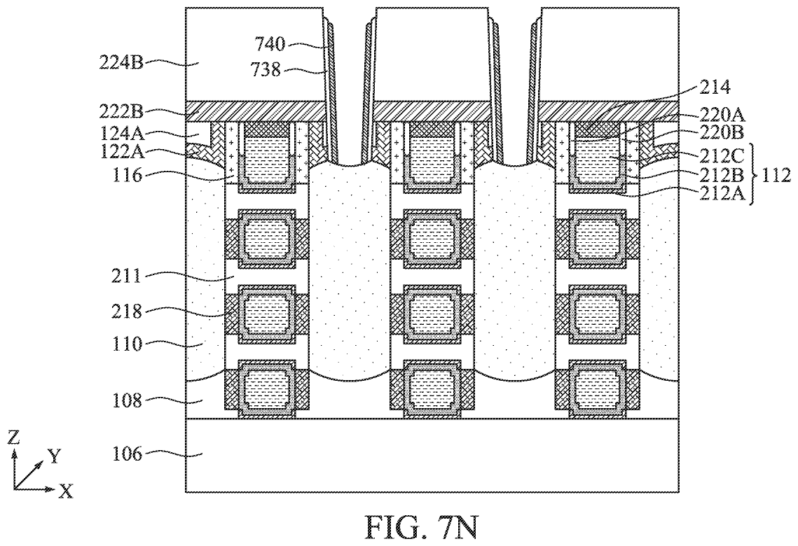

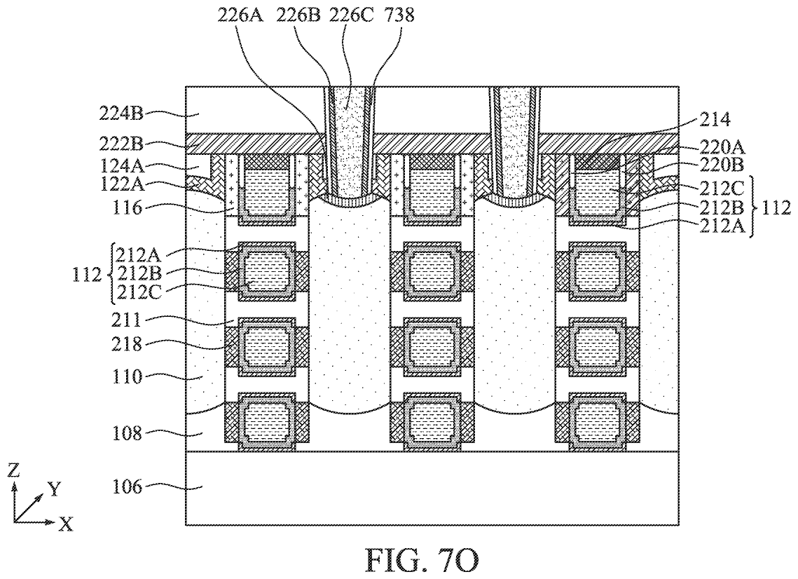

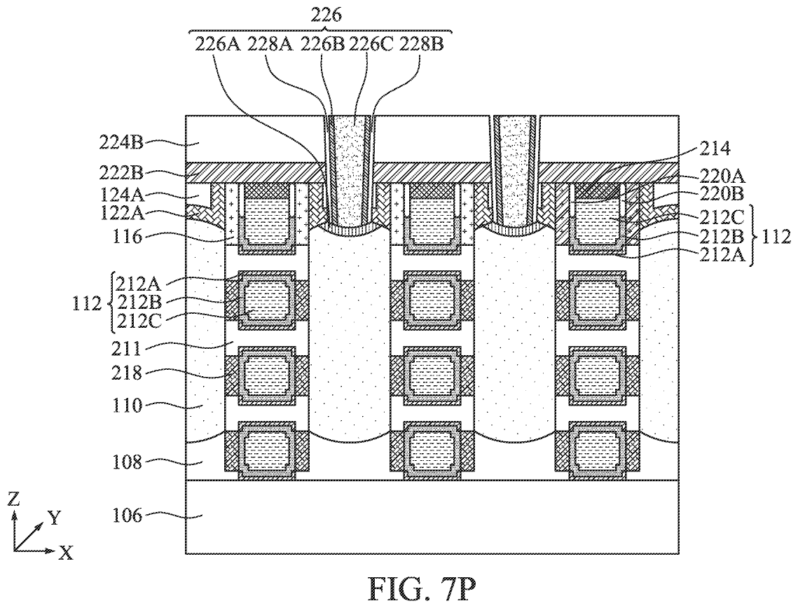

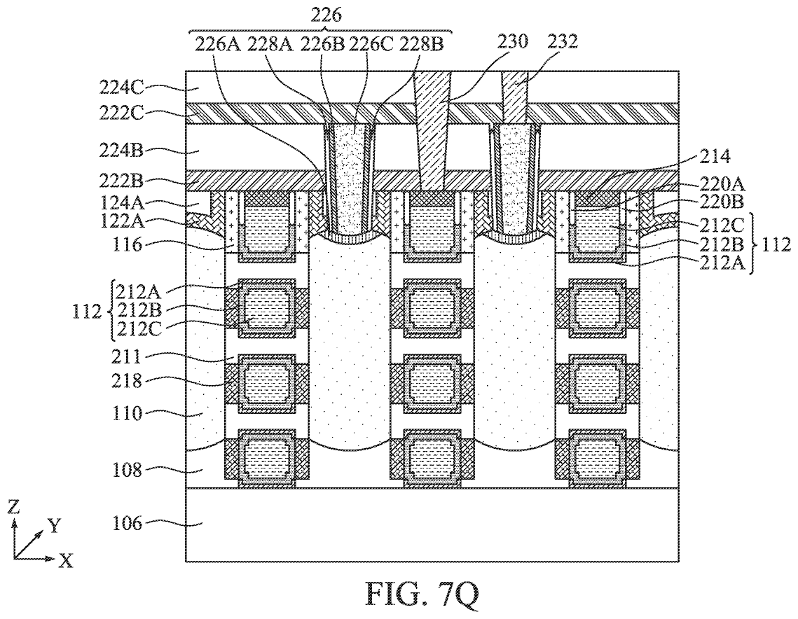

FIG. 6 is a flow diagram of an example method 600 for fabricating FET 100 with the cross-sectional view of FIG. 2A, according to some embodiments. For illustrative purposes, the operations illustrated in FIG. 6 will be described with reference to the example fabrication process for fabricating FET 100 as illustrated in FIGS. 7A-7Q. FIGS. 7A-7Q are cross-sectional views of FET 100 along line A-A of FIG. 1 at various stages of fabrication, according to some embodiments. Operations can be performed in a different order or not performed depending on specific applications. It should be noted that method 600 may not produce a complete FET 100. Accordingly, it is understood that additional processes can be provided before, during, and after method 600, and that some other processes may only be briefly described herein. Elements in FIGS. 7A-7Q with the same annotations as elements in FIGS. 1 and 2A-2C are described above.

Referring to FIG. 6, in operation 605, first and second nanostructured layers and polysilicon structures are formed on a fin structure. For example, as shown in FIG. 7A, a superlattice structures 709 having nanostructured layers 111 and 113 arranged in an alternating configuration is formed on fin structure 106 and polysilicon structures 712 are formed on superlattice structure 709. In some embodiments, nanostructured layers 111 and 113 can be epitaxially-grown on fin structure 106. In some embodiments, nanostructured layers 111 can include Si without any substantial amount of Ge (e.g., with no Ge) and nanostructured layers 113 can include SiGe. Nanostructured layers 113 are also referred to as sacrificial layers 113. During subsequent processing, sacrificial layers 113 can be replaced in a gate replacement process to form portions of gate structures 112. The formation of polysilicon structures 712 can include sequential operations of (i) depositing a polysilicon layer (not shown) on superlattice structures 709 and (ii) performing a patterning process (e.g., lithography process) on the polysilicon layer to form polysilicon structures 712, as shown in FIG. 7A. In some embodiments, gate spacers 116 can be formed after the formation of polysilicon structures 712, as shown in FIG. 7A.

Referring to FIG. 6, in operation 610, an isolation layer is formed on the fin structure and S/D regions are formed on the isolation layer. For example, as described with reference to FIGS. 7B-7E, isolation layer 108 is formed on fin structure 106 and S/D regions 110 are formed on isolation layer 108. The formation of isolation layer 108 can include sequential operations of (i) forming S/D openings 710, as shown in FIG. 7B, (ii) forming inner gate spacers 218, as shown in FIG. 7C, (iii) depositing a dielectric layer (not shown) having the material of isolation layer 108 on the structure of FIG. 7C, and (iv) etching the deposited dielectric layer to form the structure of FIG. 7D. The formation of S/D regions 110 can include epitaxially growing the semiconductor material of S/D regions 110 on the surfaces of nanostructured layers 111 facing S/D openings 710. In some embodiments, isolation layer 108 may not be formed and S/D regions 110 can be formed by epitaxially growing the semiconductor material of S/D regions 110 on fin structure 106 and on the surfaces of nanostructured layers 111 facing S/D openings 710. In some embodiments, the formation of S/D regions 110 can be followed by the formation of ESL 122A and ILD layer 124A, as shown in FIG. 7E.

Referring to FIG. 6, in operation 615, polysilicon structures and second nanostructured layers are replaced with gate structures. For example, as shown in FIG. 7F, polysilicon structures 712 and nanostructured layers 113 are replaced with gate structures 112. The replacement of polysilicon structures 712 and nanostructured layers 113 with gate structures 112 can include sequential operations of (i) etching polysilicon structures 712 from the structure of FIG. 7E, (ii) etching nanostructured layers 113 from the structure of FIG. 7E, (iii) forming IL layers 212A, as shown in FIG. 7F, by performing an oxidation process on the surfaces of nanostructured layers 111 exposed (not shown) after the etching of polysilicon structures 712 and nanostructured layers 113, (iv) depositing a high-k dielectric layer (not shown) having the material of dielectric layer 212B on the structure (not shown) formed after the formation of IL layers 212A, (v) depositing a conductive layer (not shown) having the material of conductive layer 212C on the deposited high-k dielectric, and (vi) performing a chemical mechanical polishing (CMP) process on the deposited high-k dielectric and the deposited conductive layer to form the structure of FIG. 7F.

In some embodiments during the etching of nanostructured layers 113 from the structure of FIG. 7E, portions of nanostructured layers 111 adjacent to nanostructured layers 113 can be etched to ensure complete removal of nanostructured layers 113. As a result, grooved regions are formed on nanostructured layers 111, and IL layers 212A are formed along the sidewalls of the grooved regions, as shown in FIG. 7F. And, as result of the grooved regions, the horizontal interfaces between nanostructured layers 111 and inner gate spacers 218 is at different horizontal planes than the horizontal interfaces between nanostructured layers 111 and IL layers 212A, as shown in FIG. 7F. Moreover, due to the grooved regions and IL layers 212A on the grooved regions, the cross-sectional profiles of high-k gate dielectric layers 212B and conductive layers 212C along XZ-plane can have notched corners, as shown in FIG. 7F.

Referring to FIG. 6, in operation 620, conductive capping layers are formed on the gate structures. For example, as shown in FIG. 7G, conductive capping layers 214 are formed on gate structures 112. The formation of conductive capping layers 214 can include sequential operations of (i) etching portions of conductive layers 212C from the structure of FIG. 7F to form openings (not shown) on conductive layers 212C, (ii) depositing a conductive layer (not shown) having the material of conductive capping layers 214 to fill the openings, and (iii) performing a CMP process on the deposited conductive layer to form the structure of FIG. 7G with top surfaces of conductive capping layers 214 and ILD layer 124A substantially coplanarized. In some embodiments, conductive capping layers 214 may not be formed and operation 615 can be followed by operation 625.

Referring to FIG. 6, in operation 625, gate air spacers are formed on the gate structures. For example, as shown in FIG. 7H, gate air spacers 120A and 120B are formed on gate structures 112. The formation of gate air spacers 120A and 120B can include etching portions of high-k gate dielectric layers 212B from the structure of FIG. 7G to form gate air spacers 120A and 120B, as shown in FIG. 7H. In some embodiments, the etching of high-k gate dielectric layers 212B can include performing a dry etching process on the structure of FIG. 7G using argon plasma with an etchant gas, such as chlorine-based gas, methane (CH₄)-based gas, hydrogen bromide (HBr)-based gas and boron trichloride (BCl₃)-based gas. In some embodiments, the formation of gate air spacers 120A and 120B can be followed by the formation of ESL 222B and ILD layer 224B, as shown in FIG. 7H.

In some embodiments, during the etching of high-k gate dielectric layers 212B, portions of gate spacers 116, conductive capping layers 214, and conductive layers 212C can be laterally etched along an X-axis, as shown in FIG. 7H. In some embodiments, thicknesses (e.g., about 0.5 nm to about 3 nm) of the laterally etched portions of conductive capping layers 214 are greater than thicknesses (e.g., about 0.2 nm to about 2 nm) of the laterally etched portions of gate spacers 116 because of the larger surface area of conductive capping layers 214 exposed to the etchant gas compared to that of gate spacers 116. In some embodiments, thicknesses (e.g., about 0.5 nm to about 3 nm) of the laterally etched portions of conductive capping layers 214 are greater than thicknesses (e.g., about 0.2 nm to about 2 nm) of the laterally etched portions of conductive layers 212C because conductive capping layers 214 are exposed to the etchant gas for a longer period of time than conductive layers 212C during the etching of high-k gate dielectric layers 212B. The etched profiles of gate spacers 116, conductive capping layers 214, and conductive layers 212C, as shown in FIG. 7H are not shown in FIGS. 71-7Q, 9A-9I, 11B-11L, and 13A-13I for simplicity.

In some embodiments, liners of tungsten chloride (WxCly), ruthenium chloride (RuxCly), molybdenum chloride (MoxCly), cobalt chloride (CoxCly), tungsten bromide (WxBry), ruthenium bromide (RuxBry), molybdenum bromide (MoxBry), or cobalt bromide (CoxBry) can be formed along sidewalls of conductive capping layers 214 and liners of boron nitride (BxNy) can be formed along sidewalls of gate spacers 116 during the etching of high-k gate dielectric layers 212B and can remain at the end of the etching process. On the other hand, liners are not formed along sidewalls of conductive layers 212C during the etching of high-k gate dielectric layers 212B.

Referring to FIG. 6, in operation 630, S/D contact openings are formed on the S/D regions. For example, as shown in FIG. 7I, S/D contact openings 726 are formed on S/D regions 110. The formation of S/D contact openings 726 can include dry or wet etching portions of ILD layer 224B, ESL 222B, ILD layer 124A, and ESL 122A from top surfaces of S/D regions 110, as shown in FIG. 7I.

Referring to FIG. 6, in operation 635, barrier layers are formed on exposed portions of the S/D regions in the S/D contact openings. For example, as shown in FIG. 7J, barrier layers 736 are formed on exposed portions of S/D regions 110 in S/D contact openings 726. The formation of barrier layers 736 can include oxidizing portions of the exposed surfaces of S/D regions 110 in S/D contact openings 726 by performing an oxidation process on the structure of FIG. 7I. In some embodiments, barrier layers 736 can include an oxide of the semiconductor material of S/D regions 110. In some embodiments, barrier layers 736 can include polymeric material and can be formed by depositing a polymer layer on the exposed surfaces of S/D regions 110 in S/D contact openings 726. Barrier layers 736 can protect the underlying S/D regions 110 from the processes (e.g., etch processes) performed in subsequent operation 640. In some embodiments, barrier layers 736 may not be formed and operation 630 can be followed by operation 640.

Referring to FIG. 6, in operation 640, S/D contact structures are formed in the S/D contact openings. For example, as described with reference to FIGS. 7K-7P, S/D contact structures 226 are formed in S/D contact openings 726. The formation of S/D contact structures 226 can include sequential operations of (i) depositing a substantially conformal sacrificial semiconductor layer 738 on the structure of FIG. 7J to form the structure of FIG. 7K, (ii) removing portions of sacrificial semiconductor layer 738 to form the structure of FIG. 7L, (iii) depositing a substantially conformal dielectric layer 740 having the material of diffusion barrier layers 226B on the structure of FIG. 7L to form the structure of FIG. 7M, (iv) removing portions of dielectric layer 740 and barrier layers 736 to form the structure of FIG. 7N, (v) forming silicide layers 226A on S/D regions 110, as shown in FIG. 7O, (vi) depositing a conductive layer (not shown) having the material of contact plugs 226C on silicide layers 226A to fill S/D contact openings 726, (vii) performing a CMP process on the deposited conductive layer to form the structure of FIG. 7O with top surfaces of contact plugs 226C, diffusion barrier layers 226B, sacrificial semiconductor layer 738, and ILD layer 224B substantially coplanarized, and (viii) removing sacrificial semiconductor layer 738 from sidewalls of S/D contact openings 726 to form the structure of FIG. 7P.

In some embodiments, sacrificial semiconductor layer 738 can include Si, SiGe, SiGeB, or other suitable doped or undoped semiconductor material. The removal of sacrificial semiconductor layer 738 in operations (iii) and (vii) can include performing an isotropic etch process using a fluorine-based etching gas, a chlorine-based etching gas, a bromine-based etching gas, or a combination thereof. The removal of portions of dielectric layer 740 and barrier layers 736 can include performing a dry etch process using a hydrofluoric acid gas, ammonia gas, or a combination thereof. In some embodiments, portions of both sacrificial semiconductor layer 738 and dielectric layer 740 can be etched in the same etch process (not shown) using the same etchants that have similar etch selectivity for sacrificial semiconductor layer 738 and dielectric layer 740. In some embodiments, the formation of S/D contact structures 226 can be followed by the formation of ESL 222C and ILD layer 224C, as shown in FIG. 7Q.

Referring to FIG. 6, in operation 645, a gate contact structure is formed on one of the gate structures. For example, as shown in FIG. 7Q, gate contact structure 230 can be formed on one of gate structures 112. The formation of gate contact structure 230 can include sequential operations of (i) forming a gate contact opening (not shown) on conductive capping layer 214 by etching portions of ESL 222B, ILD layer 224B, ESL 222C, and ILD layer 224C on conductive capping layer 214, (ii) depositing a conductive layer (not shown) having the material of gate contact structure 230 to fill the gate contact opening, and (iii) performing a CMP process on the deposited conductive layer to form the structure of FIG. 7Q with top surfaces of gate contact structure 230 and ILD layer 224C substantially coplanarized. In some embodiments, the formation of gate contact structure 230 can be followed by the formation of via structure 232.

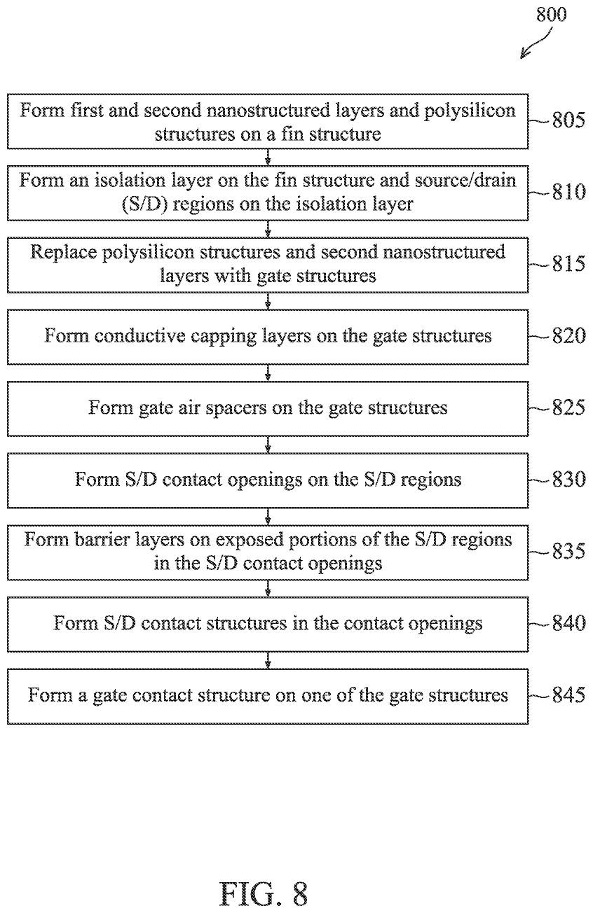

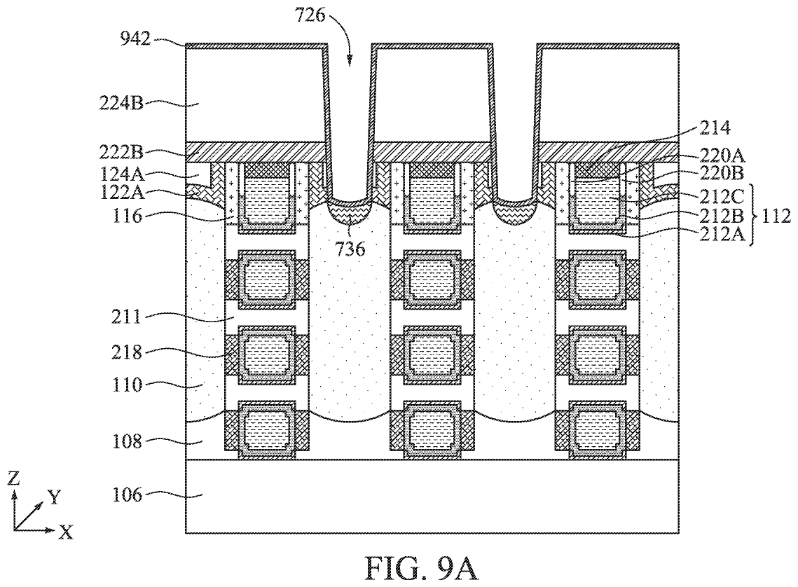

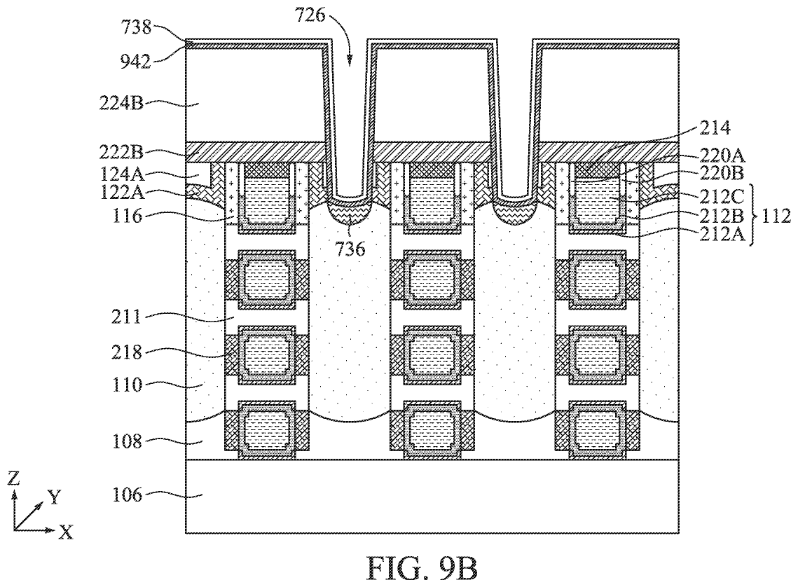

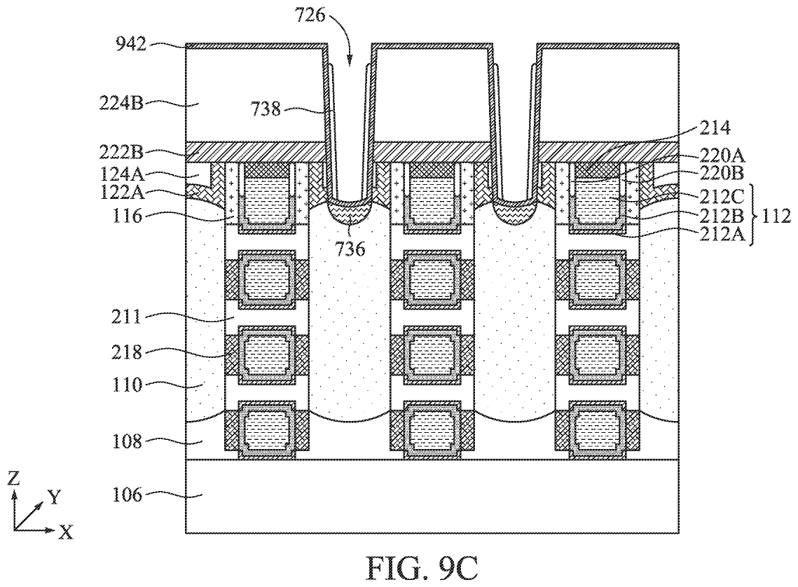

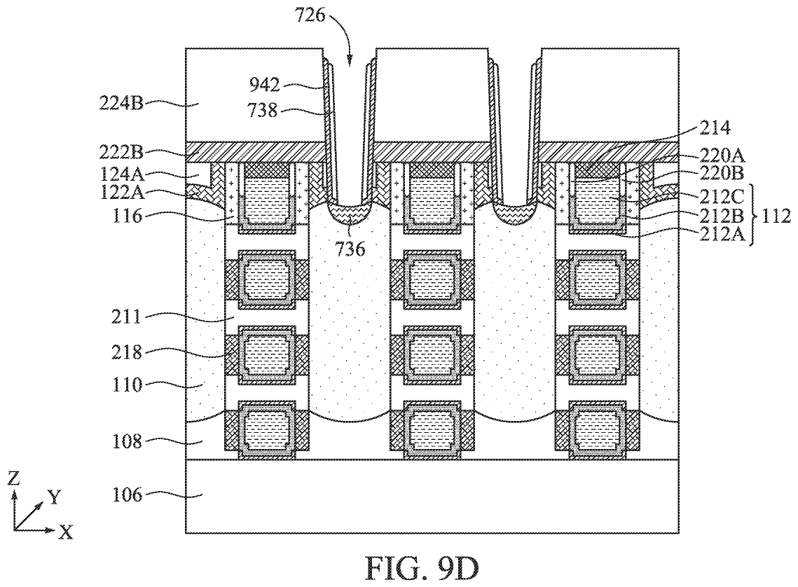

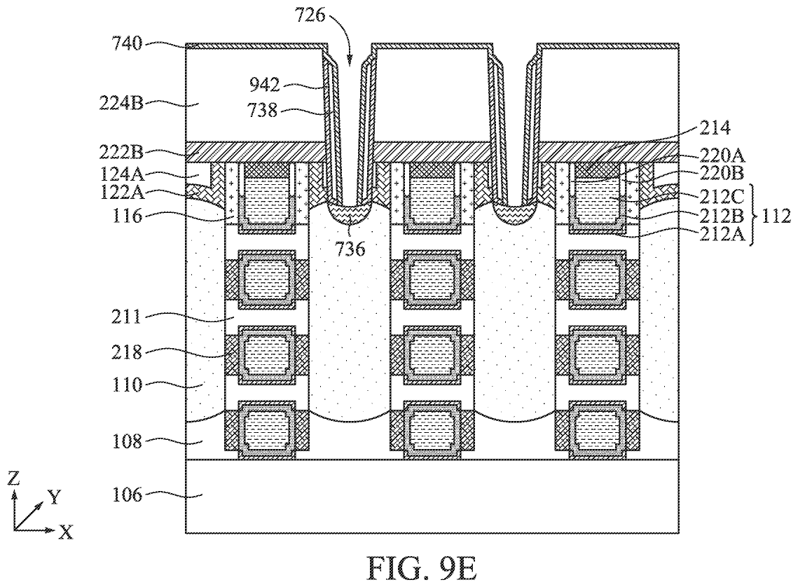

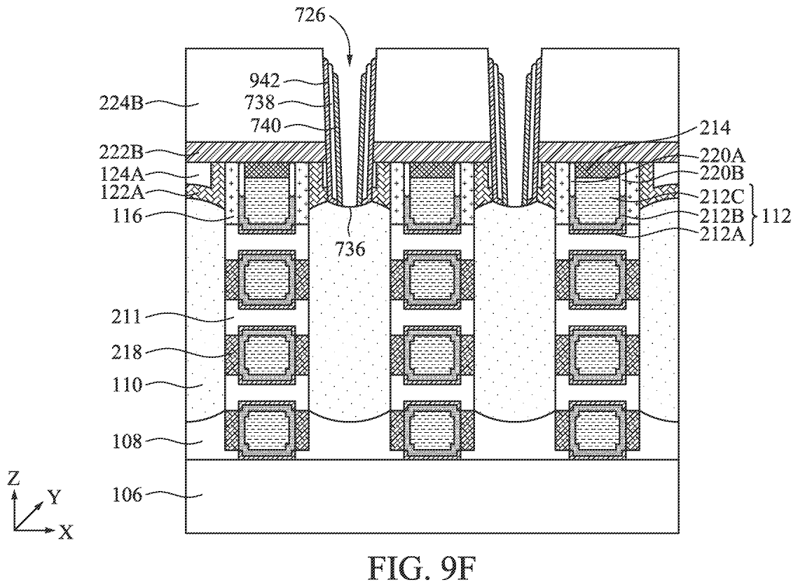

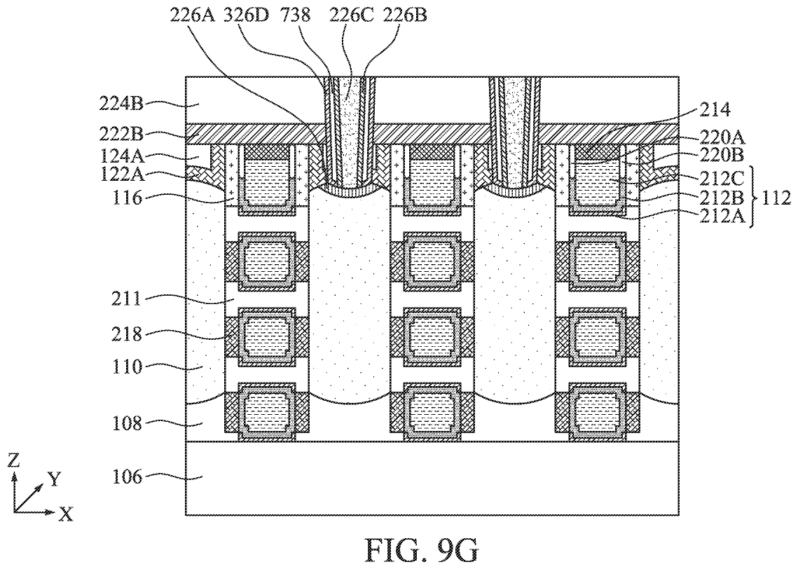

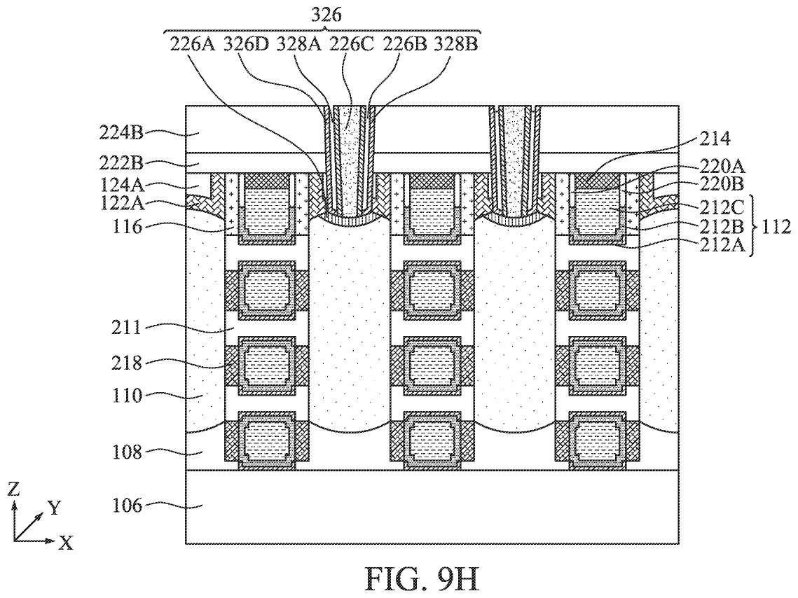

FIG. 8 is a flow diagram of an example method 800 for fabricating FET 100 with the cross-sectional view of FIG. 3A, according to some embodiments. For illustrative purposes, the operations illustrated in FIG. 8 will be described with reference to the example fabrication process for fabricating FET 100 as illustrated in FIGS. 7A-7J and 9A-9I. FIGS. 7A-7J and 9A-9I are cross-sectional views of FET 100 along line A-A of FIG. 1 at various stages of fabrication, according to some embodiments. Operations can be performed in a different order or not performed depending on specific applications. It should be noted that method 800 may not produce a complete FET 100. Accordingly, it is understood that additional processes can be provided before, during, and after method 800, and that some other processes may only be briefly described herein. Elements in FIGS. 7A-7J and 9A-9I with the same annotations as elements in FIGS. 1, 2A-2C, and 3A-3C are described above.

Referring to FIG. 8, operations 805-835 are similar to operations 605-635 of FIG. 6. The discussion of operations 605-635 applies to operations 805-835, unless mentioned otherwise. After operation 835, structure similar to the structure of FIG. 7J is formed. The subsequent processing on the structure of FIG. 7J in operations 840-845 are described with reference to FIGS. 9A-9I.

Referring to FIG. 8, in operation 840, S/D contact structures are formed in the contact openings. For example, as described with reference to FIGS. 9A-9H, S/D contact structures 326 are formed in S/D contact openings 726. The formation of S/D contact structures 326 can include sequential operations of (i) depositing a substantially conformal dielectric layer 942 having the material of dielectric liners 326D on the structure of FIG. 7J to form the structure of FIG. 9A, (ii) depositing a substantially conformal sacrificial semiconductor layer 738 on the structure of FIG. 9A to form the structure of FIG. 9B, (iii) removing portions of sacrificial semiconductor layer 738 to form the structure of FIG. 9C, (iv) removing portions of dielectric layer 942 to form the structure of FIG. 9D, (v) depositing a substantially conformal dielectric layer 740 having the material of diffusion barrier layers 226B on the structure of FIG. 9D to form the structure of FIG. 9E, (vi) removing portions of dielectric layer 740 and barrier layers 736 to form the structure of FIG. 9F, (vii) forming silicide layers 226A on S/D regions 110, as shown in FIG. 9G, (viii) depositing a conductive layer (not shown) having the material of contact plugs 226C to fill S/D contact openings 726, (ix) performing a CMP process on the deposited conductive layer to form the structure of FIG. 9G with top surfaces of contact plugs 226C, diffusion barrier layers 226B, dielectric liners 326D, sacrificial semiconductor layer 738, and ILD layer 224B substantially coplanarized, and (x) removing sacrificial semiconductor layer 738 from sidewalls of S/D contact openings 726 to form the structure of FIG. 9H.

The removal of portions of dielectric layer 942, dielectric layer 740, and barrier layers 736 can include performing a dry etch process using a hydrofluoric acid gas, ammonia gas, or a combination thereof. In some embodiments, the formation of S/D contact structures 326 can be followed by the formation of ESL 222C and ILD layer 224C, as shown in FIG. 9I.

Referring to FIG. 8, in operation 845, a gate contact structure is formed on one of the gate structures. For example, as shown in FIG. 9I, gate contact structure 230 can be formed on one of gate structures 112, as described in operation 645 of FIG. 6.

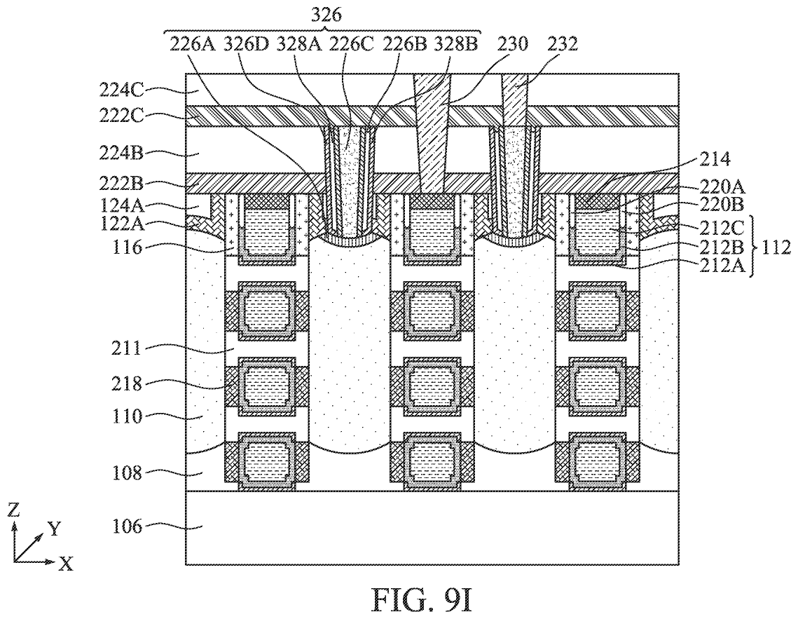

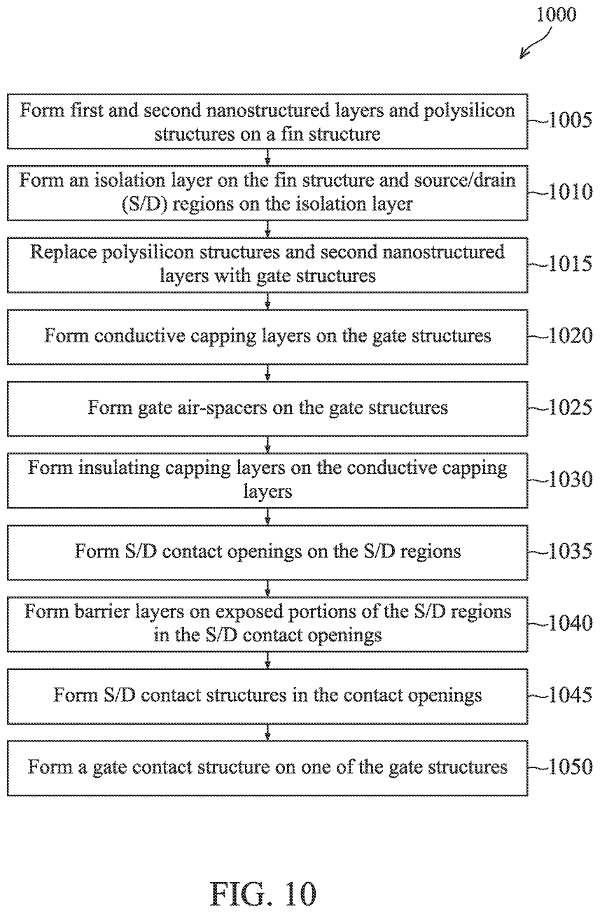

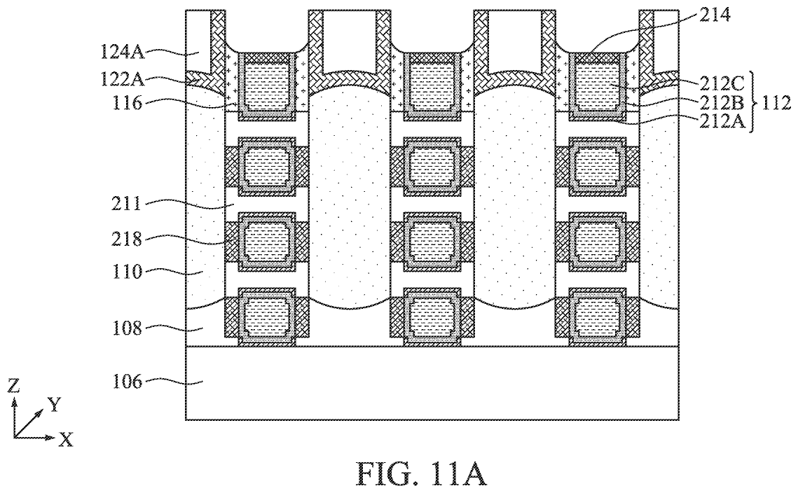

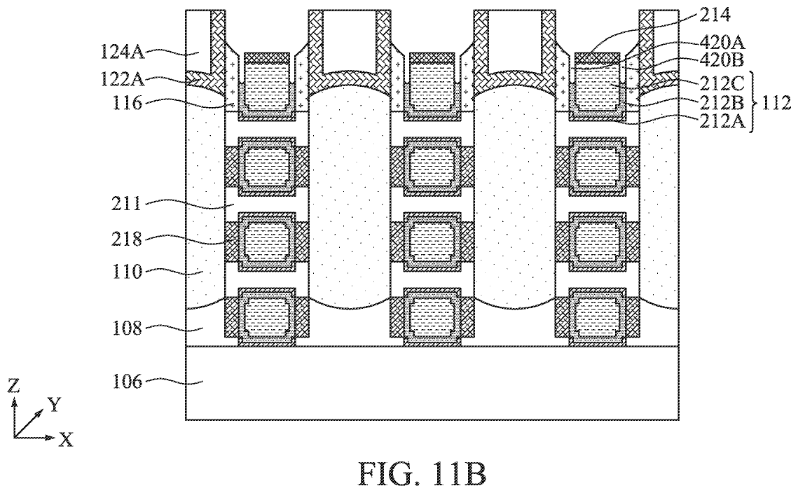

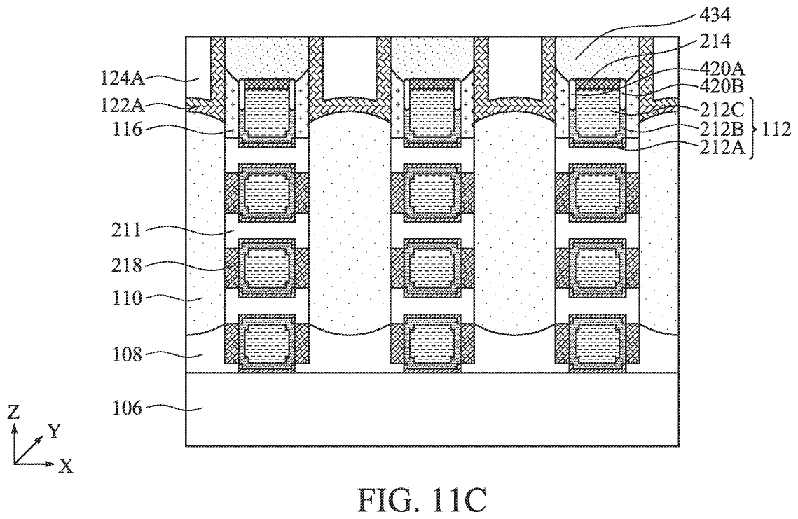

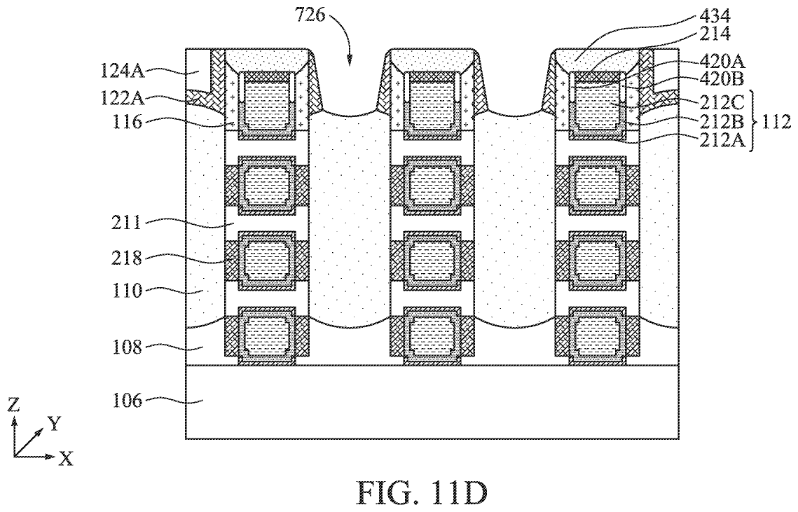

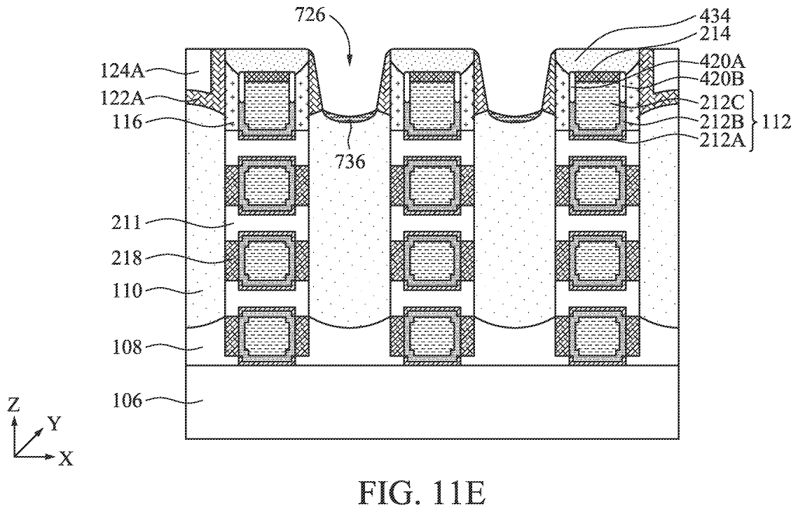

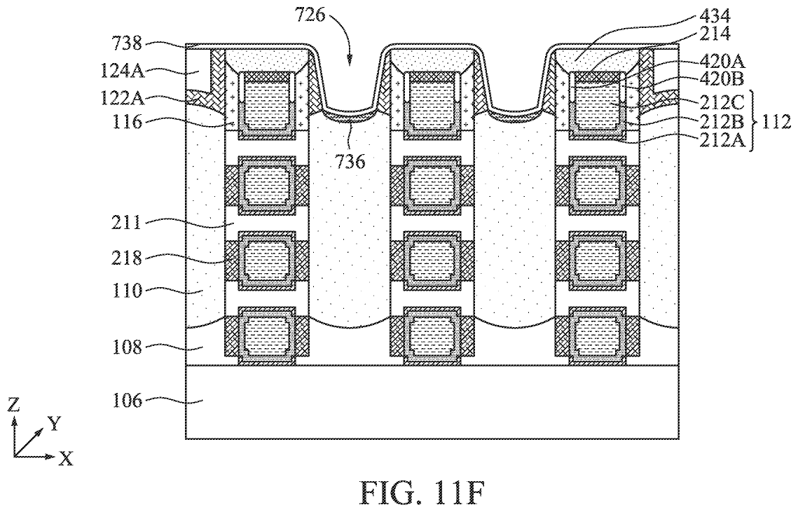

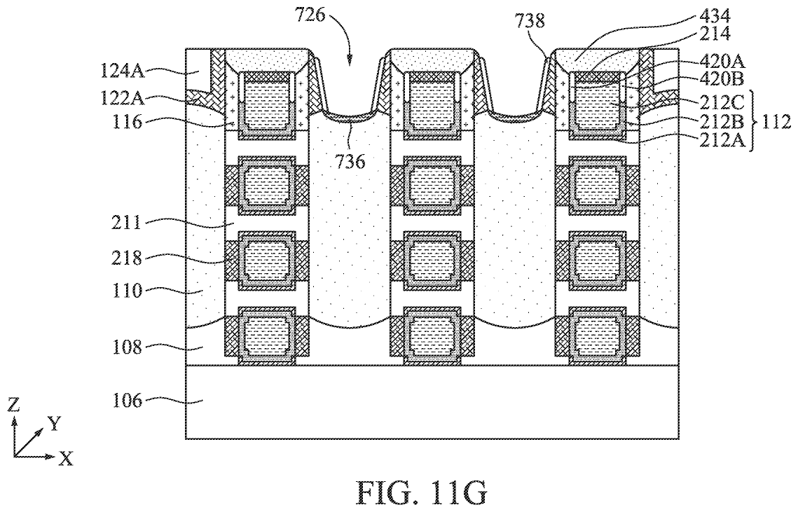

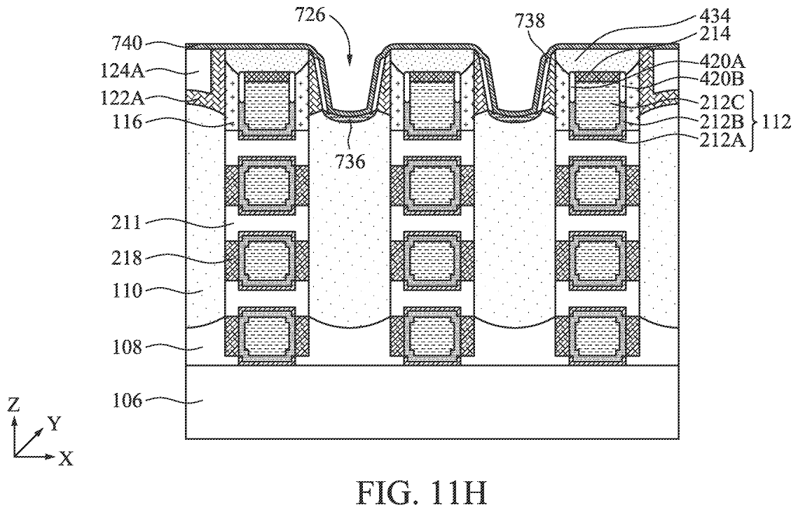

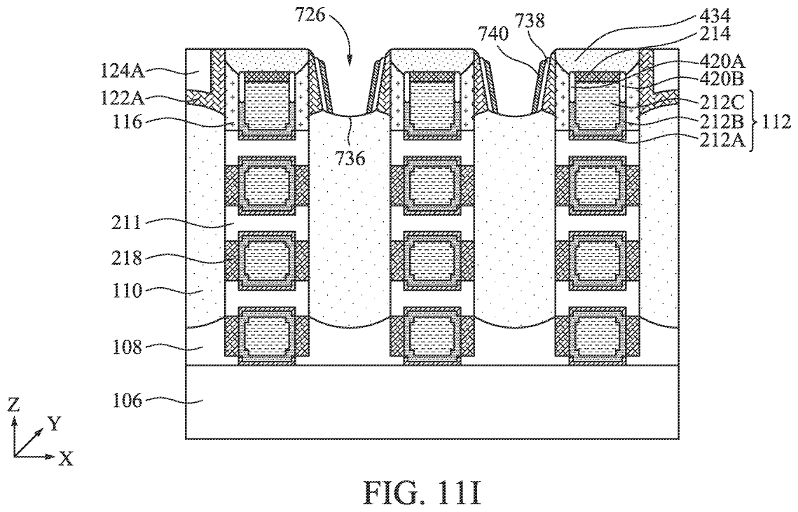

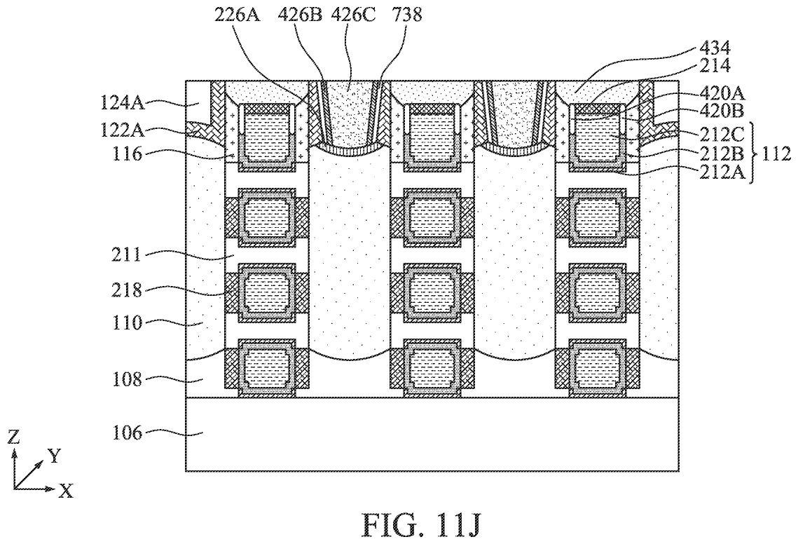

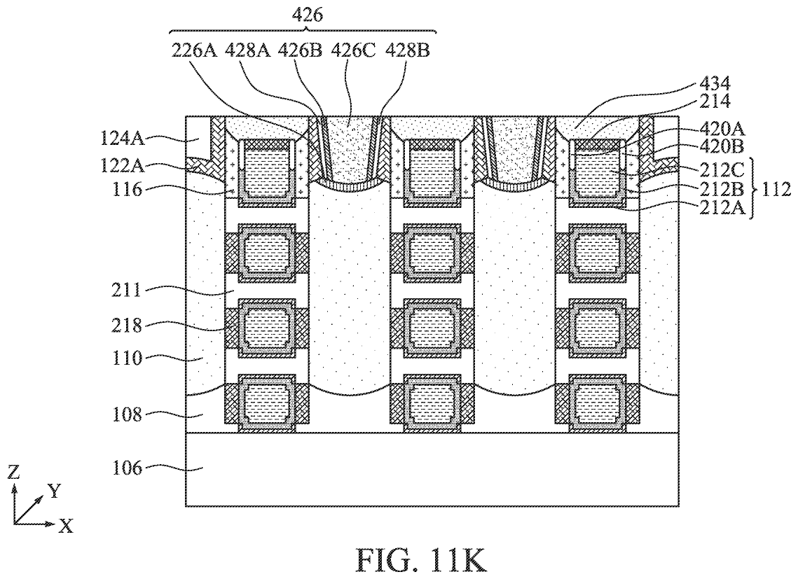

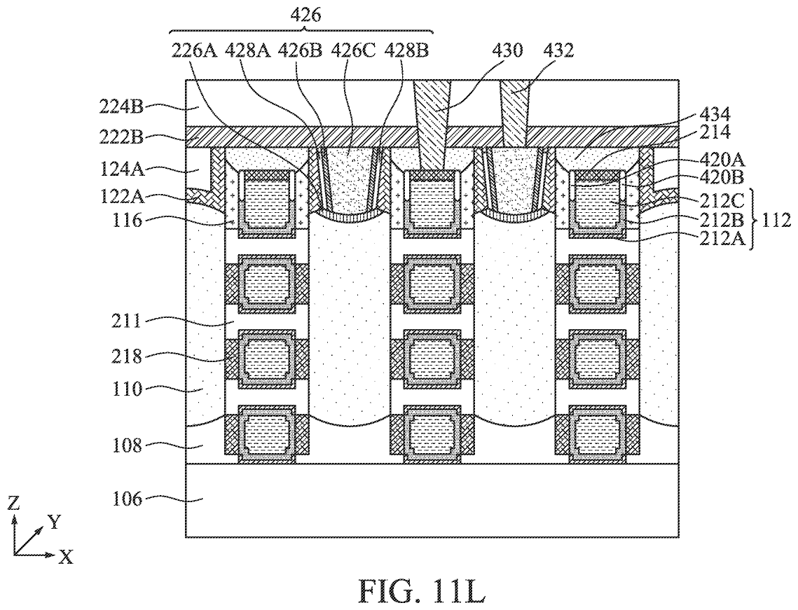

FIG. 10 is a flow diagram of an example method 1000 for fabricating FET 100 with the cross-sectional view of FIG. 4A, according to some embodiments. For illustrative purposes, the operations illustrated in FIG. 10 will be described with reference to the example fabrication process for fabricating FET 100 as illustrated in FIGS. 7A-7F and 11A-11L. FIGS. 7A-7F and 11A-11L are cross-sectional views of FET 100 along line A-A of FIG. 1 at various stages of fabrication, according to some embodiments. Operations can be performed in a different order or not performed depending on specific applications. It should be noted that method 1000 may not produce a complete FET 100. Accordingly, it is understood that additional processes can be provided before, during, and after method 1000, and that some other processes may only be briefly described herein. Elements in FIGS. 7A-7F and 11A-11L with the same annotations as elements in FIGS. 1, 2A-2C, 3A-3C, and 4A-4C are described above.

Referring to FIG. 10, operations 1005-1015 are similar to operations 605-615 of FIG. 6. The discussion of operations 605-615 applies to operations 1005-1015, unless mentioned otherwise. After operation 1015, structure similar to the structure of FIG. 7F is formed. The subsequent processing on the structure of FIG. 7F in operations 1020-1050 are described with reference to FIGS. 11A-11L.

Referring to FIG. 10, in operation 1020, conductive capping layers are formed on the gate structures. For example, as shown in FIG. 11A, conductive capping layers 214 are formed on gate structures 112. The formation of conductive capping layers 214 can include sequential operations of (i) etching portions of conductive layers 212C from the structure of FIG. 7F to form openings (not shown) on conductive layers 212C, (ii) depositing a conductive layer (not shown) having the material of conductive capping layers 214 to fill the openings, and (iii) performing a CMP process on the deposited conductive layer to form the structure of FIG. 11A with top surfaces of conductive capping layers 214 and high-k gate dielectric layers 212B substantially coplanarized. In some embodiments, conductive capping layers 214 may not be formed and operation 1015 can be followed by operation 1025. In some embodiments, top surfaces of gate spacers 116 can be etched during the etching of conductive layers 212C to form the curved etched top surface profile shown in FIG. 11A.

Referring to FIG. 10, in operation 1025, gate air spacers are formed on the gate structures. For example, as shown in FIG. 11B, gate air spacers 420A and 420B are formed on gate structures 112. The formation of gate air spacers 420A and 420B can include etching portions of high-k gate dielectric layers 212B from the structure of FIG. 11A to form gate air spacers 420A and 420B, as shown in FIG. 11B.

Referring to FIG. 10, in operation 1030, insulating capping layers are formed on the conductive capping layers. For example, as shown in FIG. 11C, insulating capping layers 434 are formed on conductive capping layers 214. The formation of insulating capping layers 434 can include sequential operations of (i) depositing an insulating layer (not shown) having the material of insulating capping layers 434 on the structure of FIG. 11B, and (ii) performing a CMP process on the deposited insulating layer to form the structure of FIG. 11C with top surfaces of insulating capping layers 434, ESL 122A, and ILD layer 124A substantially coplanarized.

Referring to FIG. 10, in operation 1035, S/D contact openings are formed on the S/D regions. For example, as shown in FIG. 11D, S/D contact openings 726 are formed on S/D regions 110. The formation of S/D contact openings 726 can include dry or wet etching portions of ILD layer 124A and ESL 122A from top surfaces of S/D regions 110, as shown in FIG. 11D.

Referring to FIG. 10, in operation 1040, barrier layers are formed on exposed portions of the S/D regions in the S/D contact openings. For example, as shown in FIG. 11E, barrier layers 736 are formed on exposed portions of S/D regions 110 in S/D contact openings 726. In some embodiments, ESLs 122A can be etched to form a tapered cross-sectional profile during the formation of S/D openings 726, as shown in FIG. 11D.

Referring to FIG. 10, in operation 1045, S/D contact structures are formed in the contact openings. For example, as described with reference to FIGS. 11F-11K, S/D contact structures 426 are formed in S/D contact openings 726. The formation of S/D contact structures 426 can include sequential operations of (i) depositing a substantially conformal sacrificial semiconductor layer 738 on the structure of FIG. 11E to form the structure of FIG. 11F, (ii) removing portions of sacrificial semiconductor layer 738 to form the structure of FIG. 11G, (iii) depositing a substantially conformal dielectric layer 740 having the material of diffusion barrier layers 426B on the structure of FIG. 11G to form the structure of FIG. 11H, (iv) removing portions of dielectric layer 740 and barrier layers 736 to form the structure of FIG. 11I, (v) depositing a conductive layer (not shown) having the material of contact plugs 426C to fill S/D contact openings 726, (vi) performing a CMP process on the deposited conductive layer to form the structure of FIG. 11J with top surfaces of contact plugs 426C, diffusion barrier layers 426B, sacrificial semiconductor layer 738, and ILD layer 124A substantially coplanarized, and (vii) removing sacrificial semiconductor layer 738 from sidewalls of S/D contact openings 726 to form the structure of FIG. 11K. In some embodiments, the formation of S/D contact structures 426 can be followed by the formation of ESL 222B and ILD layer 224B, as shown in FIG. 11L.

Referring to FIG. 10, in operation 1050, a gate contact structure is formed on one of the gate structures. For example, as shown in FIG. 11L, gate contact structure 430 can be formed on one of gate structures 112. The formation of gate contact structure 430 can include sequential operations of (i) forming a gate contact opening (not shown) on conductive capping layer 214 by etching portions of ILD layer 224B, ESL 222B, and insulating capping layers 434 on conductive capping layer 214, (ii) depositing a conductive layer (not shown) having the material of gate contact structure 430 to fill the gate contact opening, and (iii) performing a CMP process on the deposited conductive layer to form the structure of FIG. 11L with top surfaces of gate contact structure 430 and ILD layer 224B substantially coplanarized. In some embodiments, the formation of gate contact structure 430 can be followed by the formation of via structure 432.

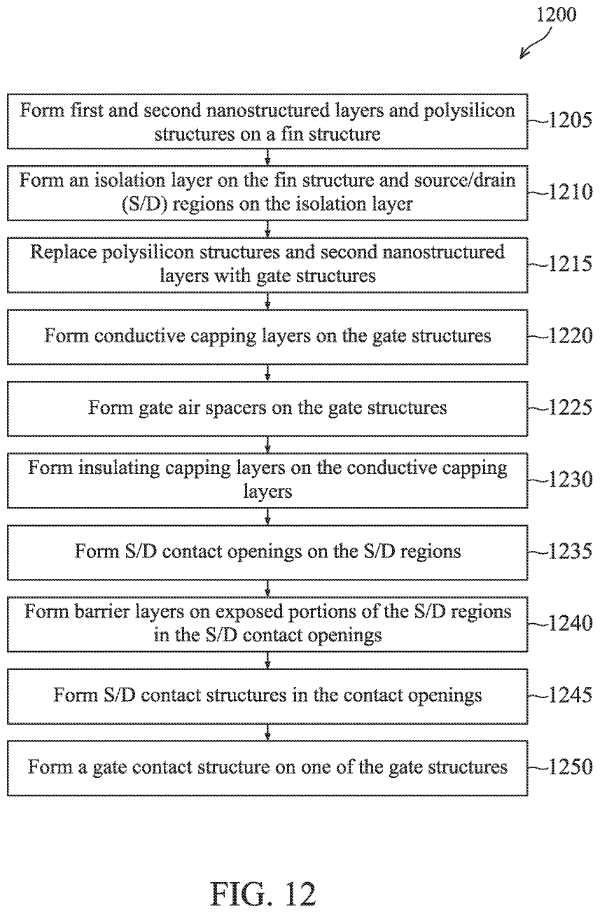

FIG. 12 is a flow diagram of an example method 1200 for fabricating FET 100 with the cross-sectional view of FIG. 5A, according to some embodiments. For illustrative purposes, the operations illustrated in FIG. 12 will be described with reference to the example fabrication process for fabricating FET 100 as illustrated in FIGS. 7A-7F, 11A-11E, and 13A-13I. FIGS. 7A-7F, 11A-11E, and 13A-13I are cross-sectional views of FET 100 along line A-A of FIG. 1 at various stages of fabrication, according to some embodiments. Operations can be performed in a different order or not performed depending on specific applications. It should be noted that method 1200 may not produce a complete FET 100. Accordingly, it is understood that additional processes can be provided before, during, and after method 1200, and that some other processes may only be briefly described herein. Elements in FIGS. 7A-7F, 11A-11E, and 13A-13I with the same annotations as elements in FIGS. 1, 2A-2C, 3A-3C, 4A-4C, and 5A-5C are described above.

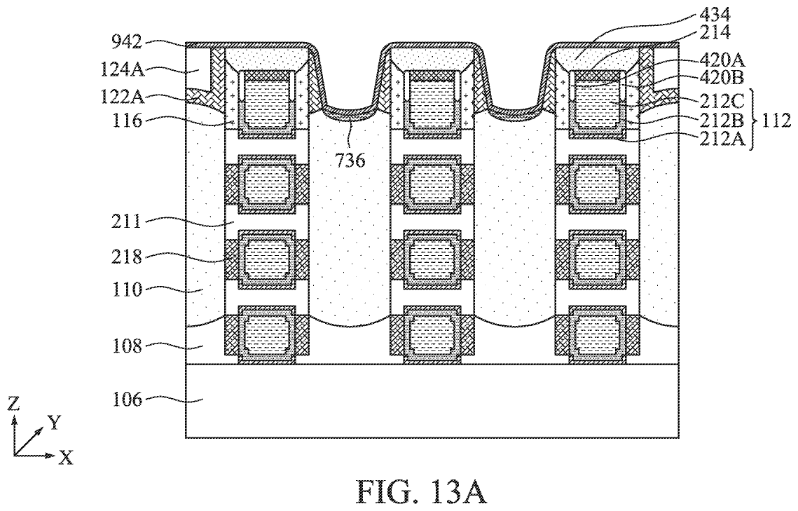

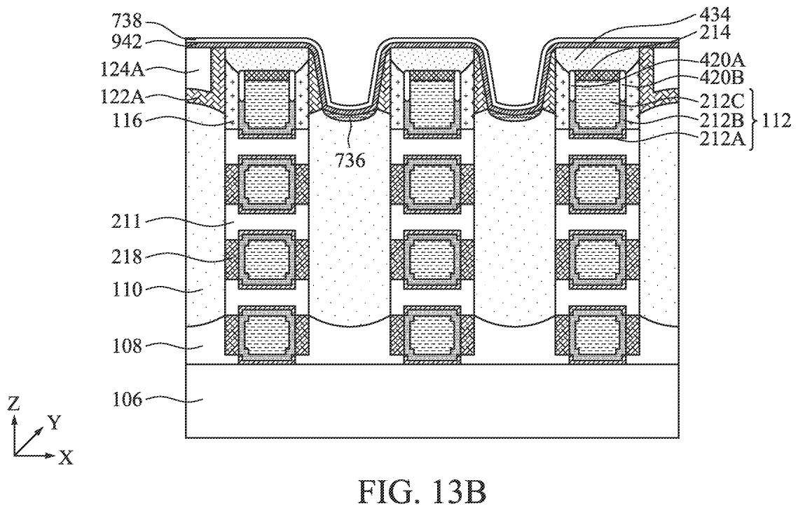

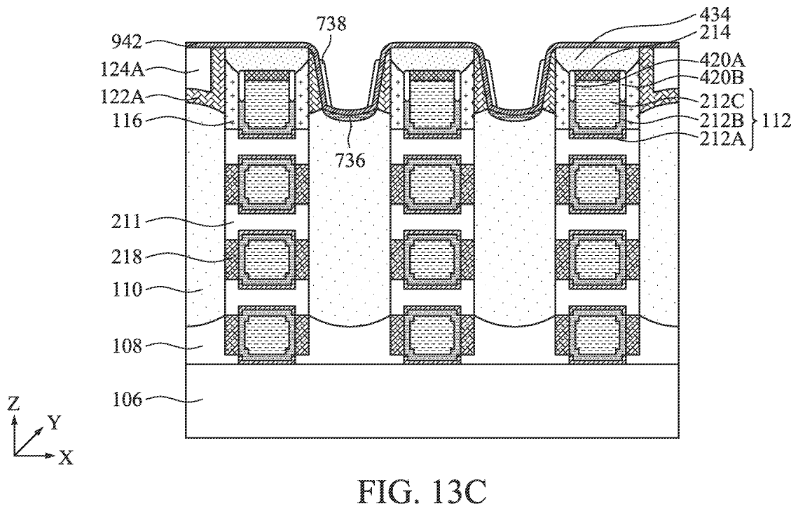

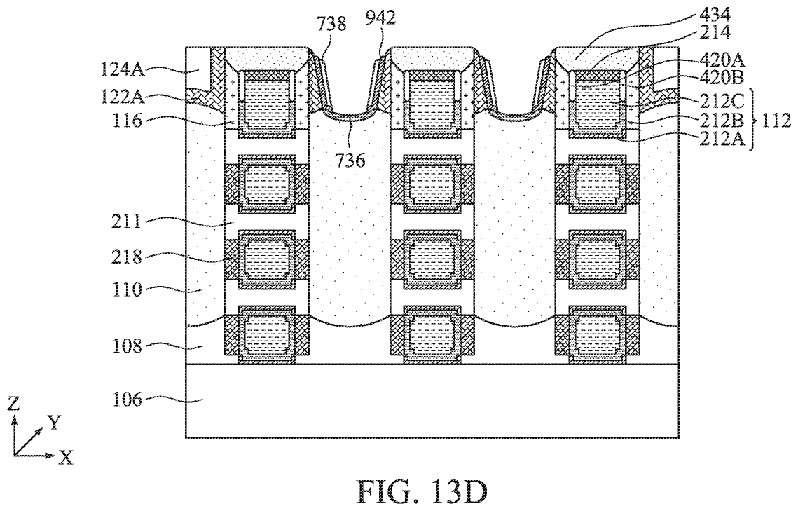

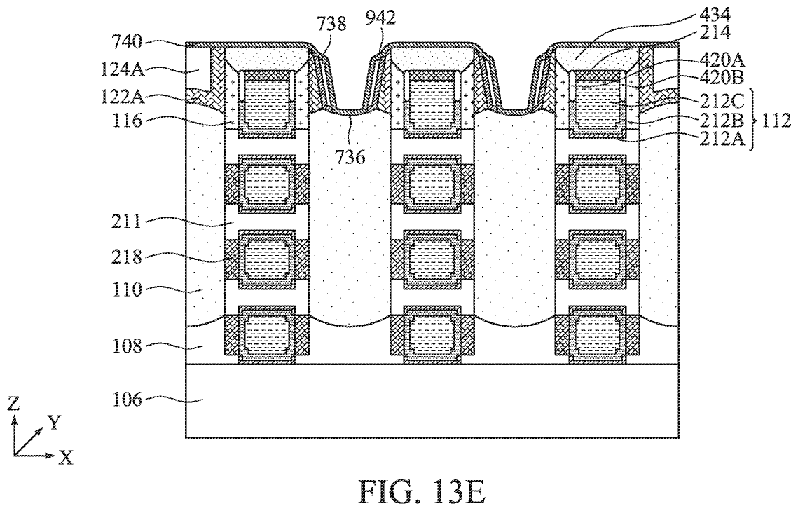

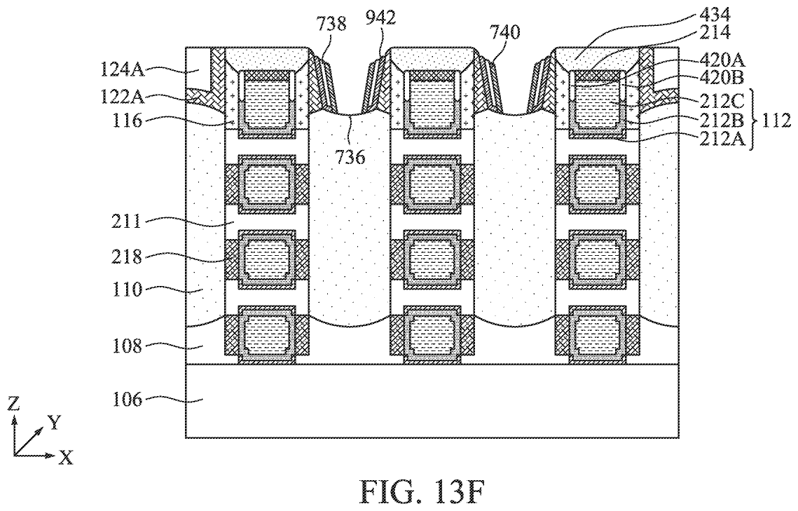

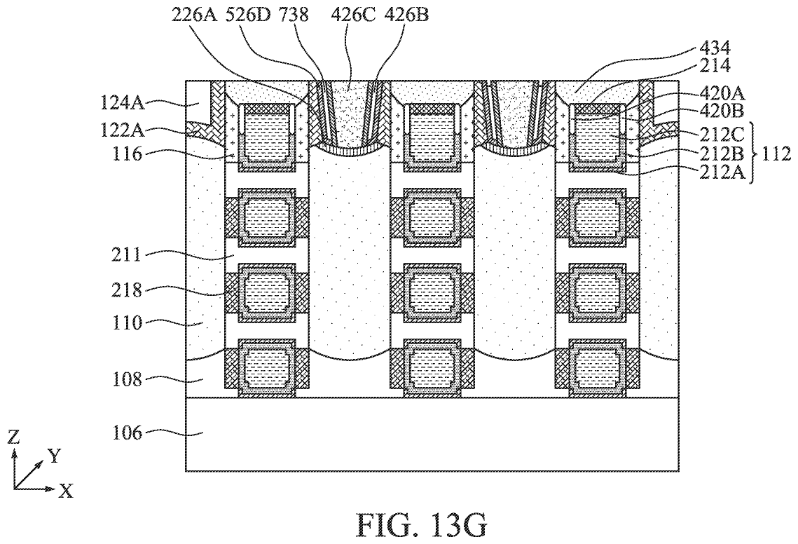

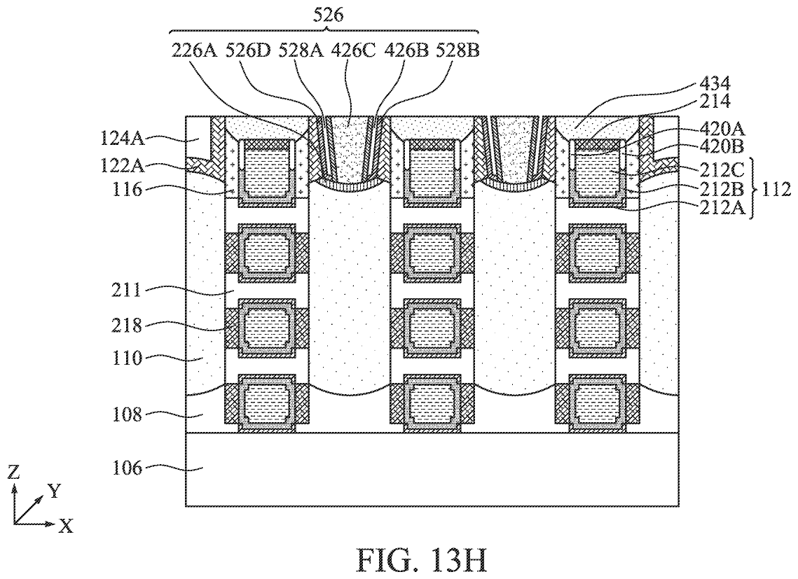

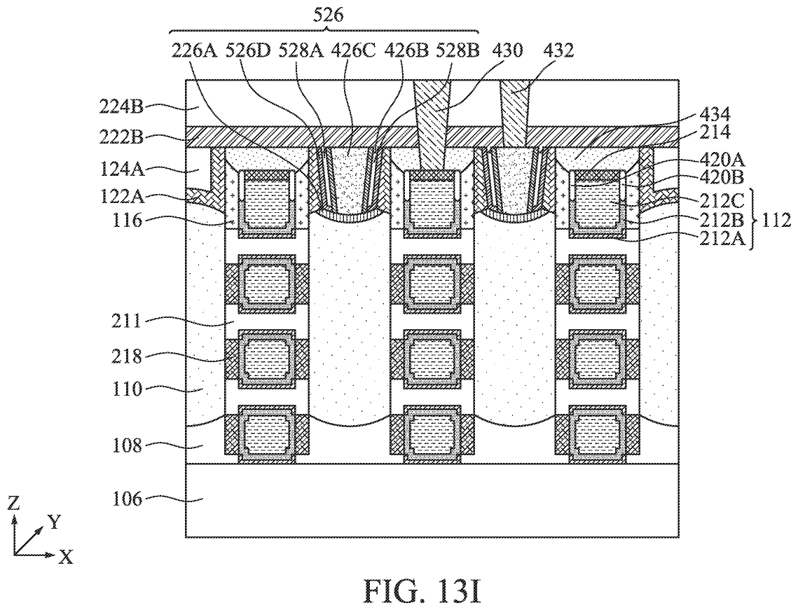

Referring to FIG. 12, operations 1205-1240 are similar to operations 1005-1040 of FIG. 10. The discussion of operations 1005-1040 applies to operations 1205-1240, unless mentioned otherwise. After operation 1240, structure similar to the structure of FIG. 11E is formed. The subsequent processing on the structure of FIG. 11E in operations 1245-1250 are described with reference to FIGS. 13A-13I.

Referring to FIG. 12, in operation 1245, S/D contact structures are formed in the contact openings. For example, as described with reference to FIGS. 13A-13H, S/D contact structures 526 are formed in S/D contact openings 726. The formation of S/D contact structures 526 can include sequential operations of (i) depositing a substantially conformal dielectric layer 942 having the material of dielectric liners 526D on the structure of FIG. 11E to form the structure of FIG. 13A, (ii) depositing a substantially conformal sacrificial semiconductor layer 738 on the structure of FIG. 13A to form the structure of FIG. 13B, (iii) removing portions of sacrificial semiconductor layer 738 to form the structure of FIG. 13C, (iv) removing portions of dielectric layer 942 to form the structure of FIG. 13D, (v) depositing a substantially conformal dielectric layer 740 having the material of diffusion barrier layers 426B on the structure of FIG. 13D to form the structure of FIG. 13E, (vi) removing portions of dielectric layer 740 and barrier layers 736 to form the structure of FIG. 13F, (vii) depositing a conductive layer (not shown) having the material of contact plugs 426C to fill S/D contact openings 726, (viii) performing a CMP process on the deposited conductive layer to form the structure of FIG. 13G with top surfaces of contact plugs 426C, diffusion barrier layers 426B, dielectric liners 526D, sacrificial semiconductor layer 738, and ILD layer 224B substantially coplanarized, and (ix) removing sacrificial semiconductor layer 738 from sidewalls of S/D contact openings 726 to form the structure of FIG. 13H.

Referring to FIG. 12, in operation 1250, a gate contact structure is formed on one of the gate structures. For example, as shown in FIG. 13I, gate contact structure 430 can be formed on one of gate structures 112, as described in operation 1050 of FIG. 10.

The formation of S/D contact structures 226 and 426 with single liners 226B and 426B, respectively, can be less complex with fewer fabrication steps than the formation of S/D contact structures 326 with dual liners 226B and 326D and the formation of S/D contact structures 526 with dual liners 426B and 526D. On the other hand, with the use of dual liners 226B and 326D in the formation of S/D contact structures 326 and the use of dual liners 426B and 526D in the formation of S/D contact structures 526, damage to S/D regions 110 during the formation of S/D contact structures 326 and 526 can be reduced or minimized compared to that in S/D regions 110 during the formation of S/D contact structures 226 and 426.

The present disclosure provides example FETs (e.g., FET 100) having air spacers and provides example methods (e.g., methods 600, 800, 1000, and 1200) of forming such FETs. In some embodiments, a FET can have gate air spacers (e.g., gate air spacers 220A, 220B, 420A, and 420B) and contact air spacers (e.g., contact air spacers 228A, 228B, 428A, and 428B). In some embodiments, the gate air spacer can be disposed between a conductive layer (e.g., conductive layer 212C) of the gate structure (e.g., gate structure 112) and a gate spacer (e.g., gate spacer 116). In some embodiments, the contact air spacer can be disposed along sidewalls of the S/D contact structure (e.g., S/D contact structures 226, 326, 426, and 526). The gate air spacers and contact air spacers reduce coupling capacitances between the gate structures and the S/D contact structures. The low dielectric constant of air in the gate air spacers and contact air spacers can reduce the coupling capacitances by about 20% to about 50% compared to FETs without such air spacers. Further, the presence of the gate air spacers and contact air spacers minimizes current leakage paths between the gate structures and the S/D contact structures. Reducing the coupling capacitances and/or current leakage in the FETs can improve the device reliability and performance compared to FETs without the gate air spacers and contact air spacers.

In some embodiments, a semiconductor device includes a substrate, nanostructured channel regions disposed on the substrate, a gate structure surrounding the nanostructured channel regions, a first air spacer disposed on the gate structure, a S/D region disposed on the substrate, and a contact structure disposed on the S/D region. The contact structure includes a silicide layer disposed on the S/D region, a conductive layer disposed on the silicide layer, a dielectric layer disposed along a sidewall of the conductive layer, and a second air spacer disposed along a sidewall of the barrier layer.

In some embodiments, a semiconductor device includes a substrate, nanostructured channel regions disposed on the substrate, a gate structure surrounding the nanostructured channel regions, a S/D region disposed on the substrate and a contact structure disposed on the S/D region. The contact structure includes a silicide layer disposed on the S/D region, a conductive layer disposed on the silicide layer, a first dielectric layer disposed along a sidewall of the conductive layer, a second dielectric layer disposed along a sidewall of the first dielectric layer, and an air spacer disposed between the first and second dielectric layers.

In some embodiments, a method includes forming a superlattice structure with first and second nanostructured layers arranged in an alternating configuration on a substrate, forming a polysilicon structure on the superlattice structure, forming a source/drain (S/D) region on the substrate, replacing the polysilicon structure and the second nanostructured layers with a gate structure, forming a first air spacer on the gate structure, forming a opening on the S/D region, forming a semiconductor layer along sidewalls of the opening, forming a conductive layer in the opening and on the semiconductor layer, and removing the semiconductor layer to form a second air spacer along sidewalls of the conductive layer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate;
nanostructured channel regions disposed on the substrate;
a gate structure surrounding the nanostructured channel regions;
a first air spacer disposed on the gate structure;
a source/drain (S/D) region disposed on the substrate; and
a contact structure disposed on the S/D region, wherein the contact structure comprises:
a silicide layer disposed on the S/D region;
a conductive layer disposed on the silicide layer;
a dielectric layer disposed along a sidewall of the conductive layer; and
a second air spacer disposed along a sidewall of the dielectric layer.

2. The semiconductor device of claim 1, further comprising a conductive capping layer disposed on the gate structure, wherein the first air spacer is disposed adjacent to the conductive capping layer.

3. The semiconductor device of claim 1, further comprising an insulating capping layer disposed on the gate structure, wherein the first air spacer is disposed between the insulating capping layer and a gate dielectric of the gate structure.

4. The semiconductor device of claim 1, wherein the first air spacer is disposed on a gate dielectric layer of the gate structure.

5. The semiconductor device of claim 1, further comprising an other dielectric layer disposed on the gate structure, wherein a portion of the other dielectric layer surrounds the first air spacer.

6. The semiconductor device of claim 1, further comprising an other dielectric layer disposed on the contact structure, wherein a portion of the other dielectric layer surrounds the second air spacer.

7. The semiconductor device of claim 1, further comprising first and second dielectric layers disposed on the first and second air spacers, respectively, wherein the second dielectric layer is disposed on the first dielectric layer.

8. The semiconductor device of claim 1, wherein the second air spacer vertically extends above a top surface of the first air spacer and vertically extends below a bottom surface of the first air spacer.

9. The semiconductor device of claim 1, wherein the second air spacer is disposed on the silicide layer.

10. The semiconductor device of claim 1, further comprising an insulating capping layer disposed on the gate structure, wherein a top surface of the insulating capping layer is coplanar with a top surface of the conductive layer.

11. The semiconductor device of claim 1, further comprising an other dielectric layer disposed between the S/D region and the substrate.

12. A semiconductor device, comprising:
a substrate;
nanostructured channel regions disposed on the substrate;
a gate structure surrounding the nanostructured channel regions;
a source/drain (S/D) region disposed on the substrate; and
a contact structure disposed on the S/D region, wherein the contact structure comprises:
a silicide layer disposed on the S/D region;
a conductive layer disposed on the silicide layer;
a first dielectric layer disposed along a sidewall of the conductive layer;
a second dielectric layer disposed along a sidewall of the first dielectric layer; and
an air spacer disposed between the first and second dielectric layers.

13. The semiconductor device of claim 12, further comprising a second air spacer disposed on a high-k gate dielectric layer of the gate structure.

14. The semiconductor device of claim 12, further comprising:
a second air spacer disposed on a high-k gate dielectric layer of the gate structure; and
a capping layer disposed on the second air spacer and the gate structure.

15. The semiconductor device of claim 12, further comprising a third dielectric layer disposed on the contact structure, wherein a portion of the third dielectric layer surrounds the air spacer.

16. The semiconductor device of claim 12, wherein the air spacer has a top surface with a tapered profile and has a bottom surface with a curved profile.

17. A method, comprising:
forming a superlattice structure with first and second nanostructured layers arranged in an alternating configuration on a substrate;
forming a polysilicon structure on the superlattice structure;
forming a source/drain (S/D) region on the substrate;
replacing the polysilicon structure and the second nanostructured layers with a gate structure;
forming a first air spacer on the gate structure;
forming a opening on the S/D region;
forming a semiconductor layer along sidewalls of the opening;
forming a conductive layer in the opening and on the semiconductor layer; and
removing the semiconductor layer to form a second air spacer along sidewalls of the conductive layer.

18. The method of claim 17, further comprising forming an oxide layer on the S/D region prior to forming the semiconductor layer.

19. The method of claim 17, further comprising forming a dielectric layer between the semiconductor layer and the conductive layer.

20. The method of claim 17, wherein forming the first air spacer comprising etching a high-k gate dielectric layer of the gate structure.
